(19) United States
(12) Patent Application Publication
(10) Pub. No.: US 2024/0324234 A1
(43) Pub. Date: Sep. 26, 2024

(54) THREE-DIMENSIONAL (3D) FERROELECTRIC RANDOM ACCESS MEMORY (FERAM) AND MANUFACTURING METHOD THEREOF

(71) Applicant: SAMSUNG ELECTRONICS CO., LTD., Suwon-si (KR)

(72) Inventors: Jeonil Lee, Suwon-si (KR); Kyunghwan Lee, Suwon-si (KR); Youngin Goh, Suwon-si (KR); Yukio Hayakawa, Suwon-si (KR)

(73) Assignee: SAMSUNG ELECTRONICS CO., LTD., Suwon-si (KR)

(21) Appl. No.: 18/430,291

(22) Filed: Feb. 1, 2024

(30) Foreign Application Priority Data
Mar. 24, 2023 (KR) 10-2023-0039111
May 17, 2023 (KR) 10-2023-0063808

(51) Int. Cl. H10B 51/20; H10B 51/30

(52) U.S. Cl. CPC H10B 51/20; H10B 51/30

(57) ABSTRACT

A 3D FeRAM is provided. The 3D FeRAM includes a semiconductor patterns stacked in a vertical direction on a substrate and spaced apart from each other in a first horizontal direction, bit lines on first side surface of the semiconductor patterns, extending in the first horizontal direction, and spaced apart from each other in the vertical direction, first electrodes on second side surfaces of the semiconductor patterns and spaced apart from each other in both the vertical direction and the first horizontal direction, a ferroelectric layer on the first electrodes, second electrodes on the ferroelectric layers, extending in the first horizontal direction, and spaced apart from each other in the vertical direction, and word lines between two adjacent semiconductor patterns extending in the vertical direction.

### CROSS-REFERENCE TO RELATED APPLICATIONS

This application claims priority to Korean Patent Application Nos. 10-2023-0039111, filed on Mar. 24, 2023, and 10-2023-0063808, filed on May 17, 2023, in the Korean Intellectual Property Office, the disclosures of which are incorporated by reference herein in their entireties.

### BACKGROUND

The present disclosure relates to a semiconductor memory device, and in particular, to a three-dimensional (3D) ferroelectric random access memory (FeRAM) and a manufacturing method thereof.

As electronic products require miniaturization, multifunctionality, and high performance, high capacity semiconductor memory devices are required and increased integration is required to provide high capacity semiconductor memory devices. Because the degree of integration of a two-dimensional (2D) semiconductor memory device is mainly determined by an area occupied by a unit memory cell, the degree of integration of the 2D semiconductor memory device is increasing but still limited. Accordingly, a 3D semiconductor memory device that increases memory capacity by stacking a plurality of memory cells in a vertical direction on a substrate has been proposed.

### SUMMARY

One or more embodiments provide a three-dimensional (3D) ferroelectric random access memory (FeRAM) with excellent endurance and no leakage problem, and a manufacturing method thereof.

Problems to be solved by the present disclosure are not limited to the above-mentioned problems, and other problems may be clearly understood by one of ordinary skill in the art from the description below.

According to an aspect of an example embodiment, there is provided a three-dimensional (3D) ferroelectric random access memory (FeRAM) including: a substrate; semiconductor patterns stacked in a vertical direction on the substrate in a multilayer structure with insulating layers therebetween, and spaced apart from each other in a first horizontal direction; bit lines on first side surfaces of the semiconductor patterns in a second horizontal direction, wherein the second horizontal direction is perpendicular to the first horizontal direction, and the bit lines extend in the first horizontal direction and are spaced apart from each other in the vertical direction; first electrodes on second side surfaces of the semiconductor patterns in the second horizontal direction, wherein the first electrodes are spaced apart from each other in both the vertical direction and the first horizontal direction; a ferroelectric layer on the first electrodes in the second horizontal direction, wherein the ferroelectric layer extends in the first horizontal direction; second electrodes on the ferroelectric layer in the second horizontal direction, wherein the second electrodes extend in the first horizontal direction and are spaced apart from each other in the vertical direction; and word lines between two adjacent semiconductor patterns among the semiconductor patterns in the first horizontal direction, wherein the word lines extend in the vertical direction.

According to another aspect of an example embodiment, there is provided a 3D FeRAM including: a substrate; semiconductor patterns stacked in a vertical direction on the substrate in a multilayer structure with insulating layers therebetween, and spaced apart from each other in a first horizontal direction; bit lines on first side surfaces of the semiconductor patterns in a second horizontal direction, wherein the second horizontal direction is perpendicular to the first horizontal direction, and the bit lines extend in the first horizontal direction and are spaced apart from each other in the vertical direction; first electrodes on second side surfaces of the semiconductor patterns in the second horizontal direction, wherein the first electrodes are spaced apart from each other in both the vertical direction and the first horizontal direction, and each of the first electrodes has a ‘ [symbol] ’ shape on each of a horizontal cross-section perpendicular to the vertical direction and a vertical cross-section perpendicular to the first horizontal direction; a ferroelectric layer on the first electrodes in the second horizontal direction, wherein the ferroelectric layer extends in the first horizontal direction, and includes a ‘ [symbol] ’-shaped portion along each of the horizontal cross-section and the vertical cross-section, in correspondence to the ‘ [symbol] ’ shape of each of the first electrodes; second electrodes on the ferroelectric layer in the second horizontal direction, wherein the second electrodes extend in the first horizontal direction and are spaced apart from each other in the vertical direction, and each of the second electrodes has a rectangular shape filling a ‘ [symbol] ’-shaped inside of the ferroelectric layer on the vertical cross-section; and word lines between two adjacent semiconductor patterns among the semiconductor patterns in the first horizontal direction, wherein the word lines extend in the vertical direction.

According to another aspect of an example embodiment, there is provided a 3D FeRAM including: a substrate; semiconductor patterns stacked in a vertical direction on the substrate in a multilayer structure with insulating layers therebetween, and spaced apart from each other in a first horizontal direction; bit lines on first side surface of the semiconductor patterns in a second horizontal direction, wherein the second horizontal direction is perpendicular to the first horizontal direction, and the bit lines extend in the first horizontal direction and are spaced apart from each other in the vertical direction; first electrodes on second side surfaces of the semiconductor patterns in the second horizontal direction, wherein the first electrodes are spaced apart from each other in both the vertical direction and the first horizontal direction, wherein each of a horizontal cross-section perpendicular to the vertical direction and a vertical cross-section perpendicular to the first horizontal direction has a rectangular shape; ferroelectric layers on the first electrodes in the second horizontal direction, wherein the ferroelectric layers in the first horizontal direction, are spaced apart from each other in the vertical direction, and have a ‘ [symbol] ’ shape on the vertical cross-section; second electrodes on the ferroelectric layers in the second horizontal direction, wherein the second electrodes extend in the first horizontal direction, are spaced apart from each other in the vertical direction, and each has a rectangular shape filling a ‘ [symbol] ’-shaped inside of each of the ferroelectric layers on the vertical cross-section; and word lines between two adjacent semiconductor patterns among the semiconductor patterns in the first horizontal direction, wherein the word lines extend in the vertical direction.

According to another aspect of an example embodiment, there is provided a substrate; semiconductor patterns stacked on the substrate in a multilayer structure with insulating layers therebetween and spaced apart from each other in a first horizontal direction; bit lines on first side surfaces of the semiconductor patterns in a second horizontal direction, wherein the second horizontal direction is perpendicular to the first horizontal direction, and the bit lines extend in a vertical direction and are spaced apart from each other in the first horizontal direction; first electrodes on second side surfaces of the semiconductor patterns in the second horizontal direction, wherein the first electrodes are spaced apart from each other in both the vertical direction and the first horizontal direction; a ferroelectric layer on the first electrodes in the second horizontal direction, wherein the ferroelectric layer extends in the vertical direction; second electrodes on the ferroelectric layer in the second horizontal direction, wherein the second electrodes extend in the vertical direction and are spaced apart from each other in the first horizontal direction; and word lines between two adjacent semiconductor patterns among the semiconductor patterns in the vertical direction, wherein the word lines extend in the first horizontal direction.

According to another aspect of an example embodiment, there is provided a manufacturing method of a 3D FeRAM including: forming a stacked structure by alternately stacking first insulating layers and semiconductor layers in a vertical direction on a substrate; separating the semiconductor layers from each other in a second horizontal direction by forming second insulating layers, wherein the second insulating layers penetrate the stacked structure, extend in a first horizontal direction, and are spaced apart from each other in the second horizontal direction, and wherein the second horizontal direction is perpendicular to the first horizontal direction; forming a first recess in the first horizontal direction by forming a first trench penetrating the stacked structure and extending in the second horizontal direction, and partially etching the semiconductor layers exposed on an inner wall of the first trench; forming first electrodes that are spaced apart from each other in the first recess in the vertical direction and the second horizontal direction, wherein each of the first electrodes has a ‘ [symbol] ’ shape on each of a vertical cross-section perpendicular to the second horizontal direction and a horizontal cross-section perpendicular to the vertical direction in the first recess; forming a ferroelectric layer which extends in the vertical direction and the second horizontal direction on the first electrodes and the second insulating layers, and includes a ‘ [symbol] ’-shaped portion along each of the horizontal cross-section and the vertical cross-section, in correspondence to a ‘ [symbol] ’shape of each of the first electrodes; forming second electrodes which extend in the second horizontal direction and are spaced apart from each other in the vertical direction on the ferroelectric layer; forming semiconductor patterns by forming a second trench penetrating the stacked structure and extending in the second horizontal direction at a position opposite to the first trench in the first horizontal direction with respect to the semiconductor layers, partially etching the semiconductor layers exposed on an inner wall of the second trench, and forming a second recess in the first horizontal direction; forming bit lines which fill the second recess, extend in the second horizontal direction, and are spaced apart from each other in the vertical direction; and forming word lines between two adjacent semiconductor patterns among the semiconductor patterns in the second horizontal direction, wherein the word lines extend in the vertical direction.

According to another aspect of an example embodiment, there is provided a manufacturing method of a 3D FeRAM including: forming a stacked structure by alternately stacking first insulating layers and semiconductor layers in a vertical direction on a substrate; forming a first recess in a second horizontal direction by forming a first trench penetrating the stacked structure and extending in a first horizontal direction, and partially etching the semiconductor layers exposed on an inner wall of the first trench, wherein the second horizontal direction is perpendicular to the first horizontal direction; forming first electrode lines in the first recess, wherein the first electrode lines extend in the first horizontal direction, are spaced apart from each other in the vertical direction, and each has a rectangular shape on a vertical cross-section perpendicular to the first horizontal direction; forming ferroelectric layers on the first electrode lines in the first recess which extend in the first horizontal direction, are spaced apart from each other in the vertical direction, and each has a ‘ [symbol] ’ shape on the vertical cross-section; forming second electrodes on the ferroelectric layers which extend in the first horizontal direction, are spaced apart from each other in the vertical direction, and each has a quadrangular shape filling a ‘ [symbol] ’-shaped inside of each of the ferroelectric layers on the vertical cross-section; forming a second recess in the second horizontal direction by forming a second trench penetrating the stacked structure and extending in the first horizontal direction at a position opposite to the first trench in the second horizontal direction with respect to the semiconductor layers, and, partially etching the semiconductor layers exposed on an inner wall of the second trench; forming bit lines which fill the second recess, extend in the first horizontal direction, and are spaced apart from each other in the vertical direction; forming first electrodes and semiconductor patterns by forming second insulating layers penetrating the stacked structure, extending in the second horizontal direction, and spaced apart from each other in the first horizontal direction; and forming word lines between two adjacent semiconductor patterns among the semiconductor patterns in the first horizontal direction, wherein the word lines extend in the vertical direction.

### BRIEF DESCRIPTION OF DRAWINGS

The above and other aspects and features will be more apparent from the following description of embodiments, taken in conjunction with the accompanying drawings, in which:

FIG. 1 is a conceptual diagram illustrating a three-dimensional (3D) ferroelectric random access memory (FeRAM) according to an embodiment;

FIGS. 2A and 2B are vertical and horizontal cross-sectional views of the 3D FeRAM of FIG. 1;

FIGS. 3A and 3B are vertical and horizontal cross-sectional views of a 3D FeRAM according to an embodiment;

FIGS. 4A and 4B are horizontal cross-sectional views of a 3D FeRAM according to an embodiment;

FIG. 5 is a conceptual diagram illustrating a 3D FeRAM according to an embodiment;

FIGS. 6A, 6B, 7A, 7B, 8A, 8B, 9A, 9B, 10A, 10B, 11A, 11B, 12A, 12B, 13A, 13B, 14A, 14B, 15A, 15B, 16A and 16B are vertical and horizontal cross-sectional views illustrating a process of manufacturing the 3D FeRAM of FIGS. 2A and 2B according to an embodiment;

FIGS. 17A and 17B are plan views illustrating a mask structure for forming a word line of the 3D FeRAM of FIG. 4A or 4B and a mask structure for forming a word line of the FeRAM of FIG. 2B or 3B, respectively according to an embodiment; and

FIGS. 18A, 18B, 19A, 19B, 20A, 20B, 21A, 21B, 22A, 22B, 23A, 23B, 24A and 24B are vertical and horizontal cross-sectional views illustrating a process of manufacturing the 3D FeRAM of FIGS. 3A and 3B according to an embodiment.

### DETAILED DESCRIPTION

Hereinafter, embodiments are described with reference to the accompanying drawings. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. It will be also understood that, even if a certain step or operation of manufacturing an apparatus or structure is described later than another step or operation, the step or operation may be performed later than the other step or operation unless the other step or operation is described as being performed after the step or operation. The same reference numerals are used for the same components in the drawings, and redundant descriptions thereof are omitted.

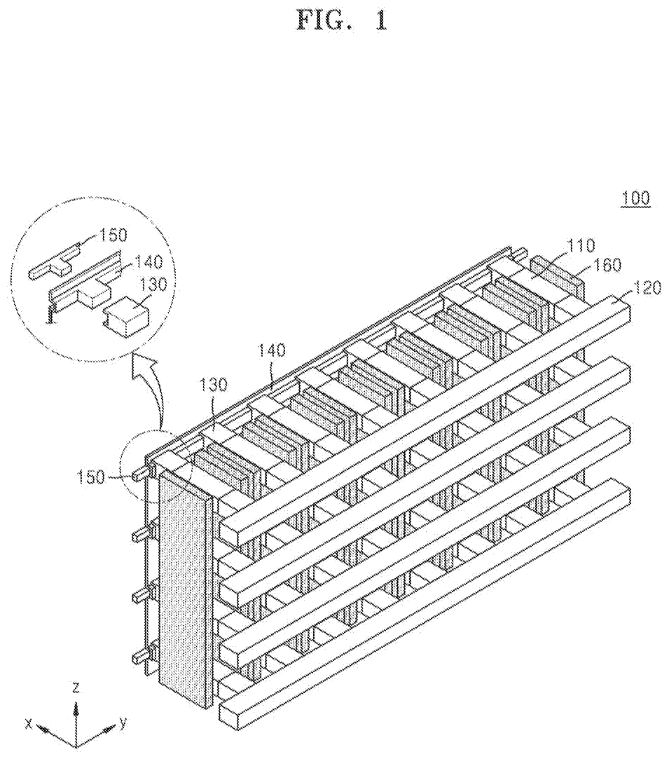

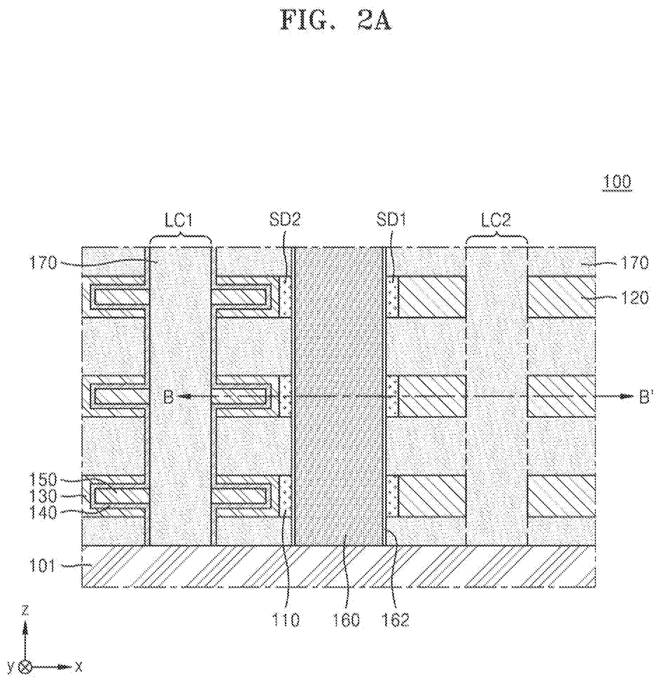

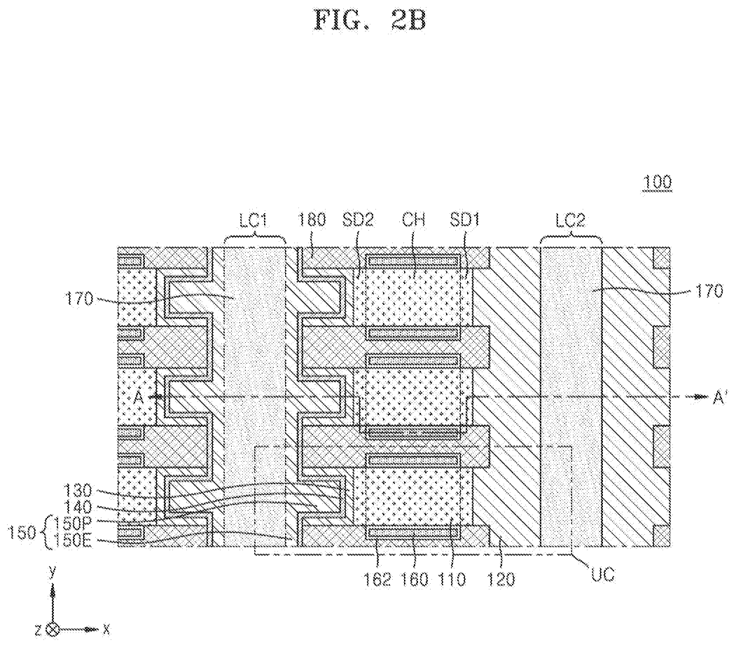

FIG. 1 is a conceptual diagram illustrating a three-dimensional (3D) ferroelectric random access memory (FeRAM) according to an embodiment. FIGS. 2A and 2B are vertical and horizontal cross-sectional views of the 3D FeRAM of FIG. 1, wherein FIG. 2A is a vertical cross-sectional view of a portion A-A′ of FIG. 2B, and FIG. 2B is a horizontal cross-sectional view of a portion B-B′ of FIG. 2A.

Referring to FIGS. 1 to 2B, a 3D FeRAM 100 may include a substrate 101, semiconductor patterns 110, bit lines 120, first electrodes 130, ferroelectric layers 140, second electrodes 150, and word lines 160.

The substrate 101 may include silicon (Si), for example, single crystal Si, polycrystalline Si (poly Si), or amorphous Si. However, a material of the substrate 101 is not limited to Si. For example, in some embodiments, the substrate 101 may include a group IV semiconductor such as germanium (Ge), a group IV-IV compound semiconductor such as silicon germanium (SiGe) or silicon carbide (SiC), or a group III-V compound semiconductor such as gallium arsenide (GaAs), indium arsenide (InAs), indium phosphide (InP), etc.

The substrate 101 may be based on a silicon bulk substrate. In addition, the substrate 101 may be based on a silicon on insulator (SOI) substrate or a germanium-on-insulator (GeOI) substrate. The substrate 101 is not limited to the bulk, SOI, or GeOI substrate, and may be a substrate based on an epitaxial wafer, a polished wafer, an annealed wafer, etc. The substrate 101 may include a conductive region, for example, a well doped with impurities, or various structures doped with impurities. In addition, the substrate 101 may constitute a P-type substrate or an N-type substrate according to the type of impurity ions to be doped. In addition, a peripheral circuit and a wiring layer connected to the peripheral circuit may be disposed on a partial region of the substrate 101.

The semiconductor patterns 110 may be alternately disposed with interlayer insulating layers 170 in a vertical direction (z direction) on the substrate 101. The semiconductor patterns 110 may be alternately disposed with isolation insulating layers 180 in a second horizontal direction (y direction). In addition, one or two word lines 160 may be disposed between two adjacent semiconductor patterns 110 in the second horizontal direction (y direction). The word line 160 may extend in the vertical direction (z direction) in a structure penetrating the isolation insulating layer 180.

The semiconductor pattern 110 may include an undoped semiconductor material or a doped semiconductor material. In some embodiments, the semiconductor pattern 110 may include a general semiconductor material such as single crystal Si, poly Si, SiGe, or SiC. In some embodiments, the semiconductor pattern 110 may include a two-dimensional (2D) semiconductor material including transition metal dichalcogenides (TMDs) such as CuS2, CuSe2, WSe2, MoS2, MoSe2, WS2, etc., hexagonal boron nitride (h-BN), graphene, carbon nano tube (CNT), or a combination thereof. In some embodiments, the semiconductor pattern 110 may include an amorphous metal oxide semiconductor material, a polycrystalline metal oxide semiconductor material, or a combination thereof. For example, a metal oxide semiconductor material may include at least one of In—Zn-based oxide (IZO), Zn—Sn-based oxide (ZTO), In—Ga-based oxide (IGO), Y—Zn-based oxide (YZO), or In—Ga—Zn-based oxide (IGZO). However, the material of the semiconductor pattern 110 is not limited to the above materials.

The semiconductor pattern 110 may have a rectangular shape elongated in the first horizontal direction (x direction). The semiconductor pattern 110 may have a rectangular pillar shape elongated in the first horizontal direction (x direction). The semiconductor pattern 110 may include a channel region CH in a central portion in a first horizontal direction (x direction) and a first impurity region SD1 and a second impurity region SD2 on both sides of the channel region CH in the first horizontal direction (x direction). The first impurity region SD1 may be connected to the bit line 120, and the second impurity region SD2 may be connected to the first electrode 130.

The first impurity region SD1 and the second impurity region SD2 may be formed by doping impurity ions on both sides of the semiconductor pattern 110 in the first horizontal direction (x direction) by using gas phase doping. The first impurity region SD1 and the second impurity region SD2 may respectively constitute, for example, a source junction and a drain junction. In addition, for ohmic contact with a metal, a silicide layer may be formed between the first impurity region SD1 and the bit line 120 and between the second impurity region SD2 and the first electrode 130. The silicide layer may include, for example, at least one of titanium (Ti) silicide, tungsten (W) silicide, cobalt (Co) silicide, or nickel (Ni) silicide.

The bit lines 120 may be spaced apart from each other on the substrate 101 in the vertical direction (z direction) and disposed at positions corresponding to the semiconductor pattern 110. In addition, a bit line 120 may be disposed on one side of the semiconductor pattern 110 in the first horizontal direction (x direction) and extend in the second horizontal direction (y direction). For example, in one layer in the vertical direction (z direction), the semiconductor patterns 110 disposed in the second horizontal direction (y direction) may be connected to the bit lines 120 disposed on the corresponding layer.

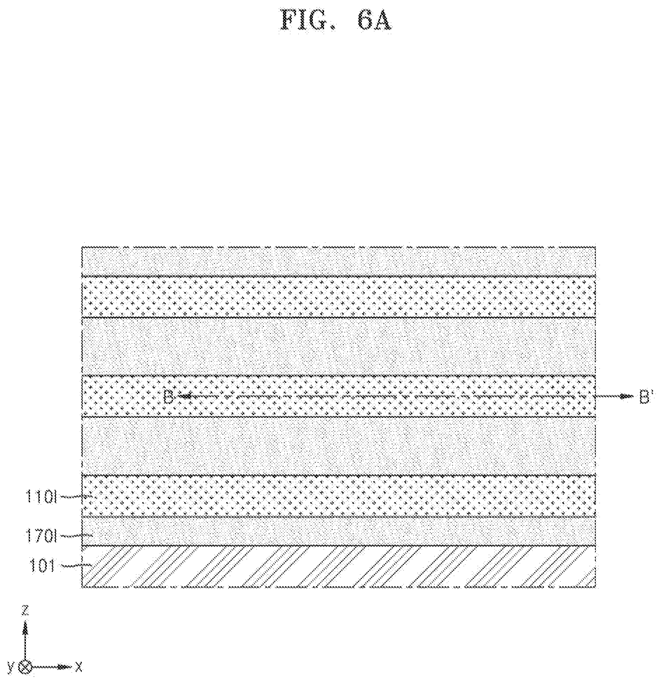

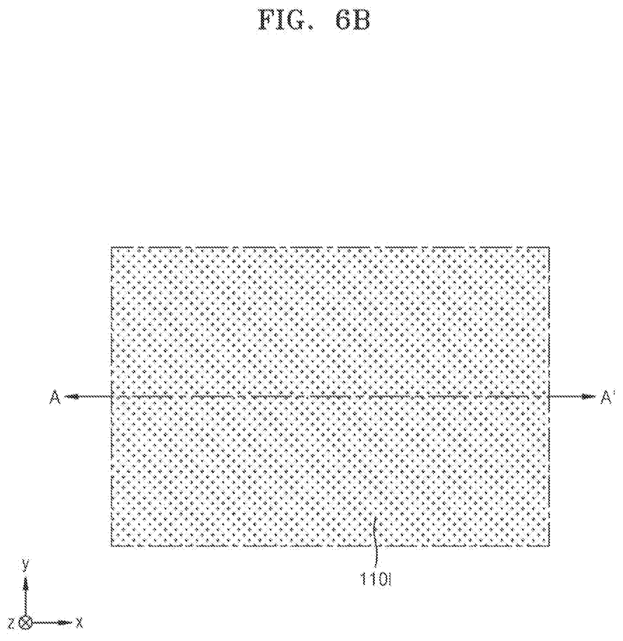

A side surface of a bit line 120 contacting the semiconductor pattern 110 in the first horizontal direction (x direction) may have a concave-convex shape in the second horizontal direction (y direction), and an opposite side surface thereof may have a straight line shape in the second horizontal direction (y direction). The one side surface of the bit line 120 may have the concave-convex shape because the 3D FeRAM 100 includes the isolation insulating layer 180, and an etching rate between the interlayer insulating layer 170 and the isolation insulating layer 180 differs. The structure of the bit line 120 is described in more detail in the description of a manufacturing method of the 3D FeRAM 100 of FIGS. 6A to 16B.

The bit line 120 may include a conductive material. The bit line 120 may include, for example, any one of a doped semiconductor material, a metal, a conductive metal nitride, and a metal-semiconductor compound.

The first electrodes 130 may be spaced apart from each other on the substrate 101 in the vertical direction (z direction) and may be disposed at positions corresponding to the semiconductor pattern 110. In addition, the first electrodes 130 may be disposed on one side surface of the semiconductor patterns 110 in the first horizontal direction (x direction) and be spaced apart from each other in the second horizontal direction (y direction). For example, the bit line 120 may be disposed on one side surface of the semiconductor pattern 110 in the first horizontal direction (x direction), and the first electrode 130 may be disposed on the other side surface thereof in the first horizontal direction (x direction).

Unlike the bit line 120, the first electrodes 130 may be respectively connected to the semiconductor patterns 110. In this regard, like the semiconductor patterns 110, the first electrodes 130 may be spaced apart from each other in the vertical direction (z direction) and the second horizontal direction (y direction). As may be seen in FIGS. 2A and 2B, the horizontal cross-section and the vertical cross-section of the first electrode 130 may be in the ‘ [symbol] ’ shape. Here, the vertical section may indicate a section perpendicular to the second horizontal direction (y direction). Accordingly, the first electrode 130 may have a shape of a rectangular tube in which the side of the semiconductor pattern 110 is closed in the first horizontal direction (x direction) and the other side thereof is opened three-dimensionally.

The first electrode 130 may include any one of a doped semiconductor material, a metal, a conductive metal nitride, and a conductive metal oxide. Here, the metal may include, for example, ruthenium, iridium, titanium, tantalum, etc. The conductive metal nitride may include titanium nitride, tantalum nitride, niobium nitride, tungsten nitride, etc. The conductive metal oxide may include iridium oxide, niobium oxide, etc. However, a material of the first electrode 130 is not limited to the above materials.

The ferroelectric layer 140 may extend from the substrate 101 in the vertical direction (z direction) and may also extend in the second horizontal direction (y direction). The ferroelectric layer 140 may be connected to the first electrode 130 and include a ‘ [symbol] ’ shaped portion at a position corresponding to the semiconductor pattern 110 in the vertical direction (z direction) and the second horizontal direction (y direction). That is, the ferroelectric layer 140 may include the ‘ [symbol] ’-shaped portion on the horizontal cross-section and the vertical cross-section, in correspondence to the first electrode 130 having the ‘ [symbol] ’ shape.

In FIGS. 2A and 2B, a first line cut LC1 may be a region used to form the first electrode 130, the ferroelectric layer 140, and the second electrode 150, and may be filled by the interlayer insulating layer 170 in the final structure. The first line cut LC1 may extend in the vertical direction (z direction) and the second horizontal direction (y direction) and may have a somewhat uniform width in the first horizontal direction (x direction). In FIG. 2A, an outer side surface of the ferroelectric layer 140 may contact the first line cut LC1 in the first horizontal direction (x direction). On the other hand, in FIG. 2B, the outer side surface of the ferroelectric layer 140 in the first horizontal direction (x direction) may be spaced apart from the first line cut LC1, and a part of the second electrode 150 may be disposed therebetween. The structure of the ferroelectric layer 140 is described in more detail in the description of the manufacturing method of 3D FeRAM of FIGS. 6A to 16B.

The ferroelectric layer 140 may include a ferroelectric material. For example, the ferroelectric layer 140 may include a hafnium (Hf)-based oxide. Specifically, the Hf-based oxide may include hafnium oxide (HfO), hafnium silicate (HfSiO), hafnium oxynitride (HfON), hafnium silicon oxynitride (HfSiON), etc. When the ferroelectric layer 140 includes the Hf-based oxide, the ferroelectric layer 140 may include a dopant of at least one of Zr, Si, Al, Y, Gd, La, Sc, and Sr. However, a material of the ferroelectric layer 140 is not limited to the above materials.

Moreover, the ferroelectric layer 140 may include a single layer or multiple layers. When the ferroelectric layer 140 includes multiple layers, both outermost parts thereof may include ferroelectric thin films. As a specific example, the ferroelectric layer 140 may have a triple layer structure of a first ferroelectric thin film, an AlO thin film, and a second ferroelectric thin film. Also, the ferroelectric layer 140 may have a five layer structure of the first ferroelectric thin film, a first AlO thin film, the second ferroelectric thin film, a second AlO thin film, and a third ferroelectric thin film. However, a multilayer structure of the ferroelectric layer 140 is not limited to the triple layer or five layer structure.

The second electrodes 150 may be spaced apart from each other on the substrate 101 in the vertical direction (z direction) and may be disposed at a position corresponding to the semiconductor pattern 110. The second electrode 150 may be disposed on one side surface of the ferroelectric layer 140 in the first horizontal direction (x direction) and extend in the second horizontal direction (y direction). That is, the first electrode 130 may be disposed on one side surface of the ferroelectric layer 140 in the first horizontal direction (x direction) and the second electrode 150 may be disposed on the other side surface thereof.

As may be seen in FIG. 2B, the second electrode 150 may include an extension 150E extending in the second horizontal direction (y direction) on the horizontal cross-section and a protrusion 150P protruding from the extension 150E in the first horizontal direction (x direction) in correspondence to the ferroelectric layer 140 having the ‘ [symbol] ’ shape on the horizontal cross-section. In addition, as may be seen in FIG. 2A, a vertical cross-section of the second electrode 150 may have a quadrangular shape filling a ‘ [symbol] ’ shaped inside of the ferroelectric layer 140. The second electrode 150 may include substantially the same conductive material as that of the first electrode 130. However, according to an embodiment, the second electrode 150 may include a conductive material that is different from that of the first electrode 130.

In addition, the first electrode 130, the ferroelectric layer 140, and the second electrode 150 may constitute a ferroelectric capacitor (hereinafter referred to as ‘FeCap’). FeCap may store information of [0] or [1] due to a hysteresis characteristic with respect to a dielectric polarization of the ferroelectric layer 140. For reference, FeRAM may be classified into a 1Tr1Cap type in which FeCap is disposed between a bit line and a transistor Tr, similar to DRAM, and a 1Tr type in which a gate dielectric film of an FET is replaced with a ferroelectric layer, similar to the FET. The 3D FeRAM 100 may belong to, for example, the 1TR1Cap type.

The word line 160 may extend from the substrate 101 in the vertical direction (z direction) and may be disposed in the second horizontal direction (y direction). As may be seen from FIGS. 1 and 2B, two word lines 160 may be disposed between adjacent semiconductor patterns 110 in the second horizontal direction (y direction). Furthermore, the word line 160 may be surrounded by a gate dielectric layer 162. Accordingly, the gate dielectric layer 162 may be disposed between the semiconductor pattern 110 and the word line 160.

Furthermore, in a structure in which two word lines 160 are disposed between the adjacent semiconductor patterns 110, a double gate transistor in which the word lines 160 are disposed on both sides of the channel region CH may be configured. Accordingly, as indicated by a rectangle of a dotted-dot chain line in FIG. 2B, one semiconductor pattern 110, the word lines 160 on both sides of the corresponding semiconductor pattern 110 in the second horizontal direction (y direction), and the bit line 120 and the FeCap connected to the corresponding semiconductor pattern 110 in the first horizontal direction (x direction) may constitute a unit cell UC. For reference, in FIGS. 2A and 2B, the 3D FeRAM 100 may have a left-right symmetrical structure with respect to a center line of each of the first line cut LC1 and a second line cut LC2.

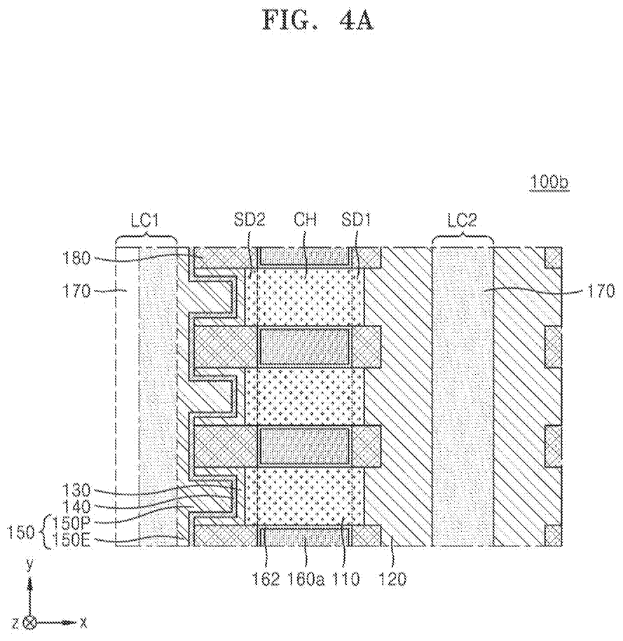

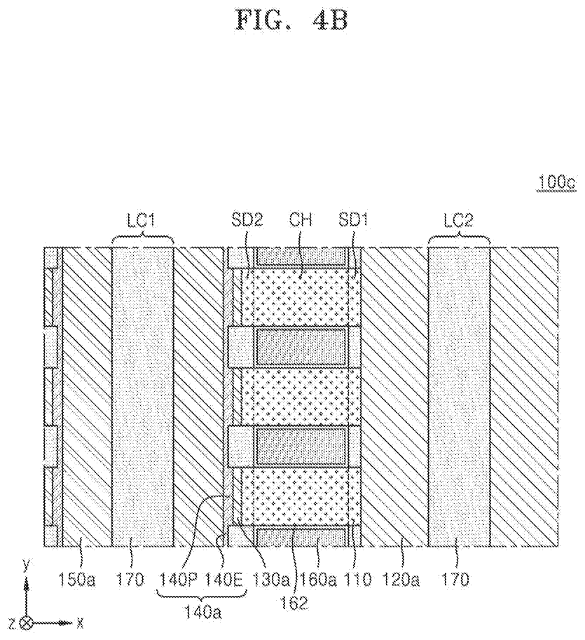

According to an embodiment, one word line 160 may be disposed between the adjacent semiconductor patterns 110 in the second horizontal direction (y direction). In a structure in which one word line 160 is disposed between adjacent semiconductor patterns 110, the single gate transistor having one word line 160 disposed in each channel region CH may be formed. The structure in which one word line 160 is disposed between the adjacent semiconductor patterns 110 is described in detail with reference to FIGS. 4A and 4B.

The 3D FeRAM 100 has a 1TR1Cap structure, thereby solving an endurance problem of FeRAM of 1Tr structure (i.e., FeFET) and also solving a problem of having to stack channels of single-crystal Si caused by a leakage issue in a vertical stack (VS)-DRAM. That is, in the 3D FeRAM 100, even when poly Si is used for the semiconductor pattern 110 constituting a channel, a leakage problem may not occur. In addition, the 3D FeRAM 100 may have a structure in which the second electrodes 150 are separated from each other in correspondence to the bit lines 120 for each layer in the vertical direction (z direction). As described above, the second electrodes 150 are separated in the vertical direction (z direction), which may solve a read disturb problem caused by a structure in which the second electrodes 150 are tied together in the form of a plate electrode, and accordingly, the reliability of FeRAM may be greatly improved. For reference, as may be seen in FIG. 2A, the 3D FeRAM 100 may have a structure in which in one layer in the vertical direction (z direction), the horizontal channel region CH, the horizontal bit line 120, the horizontal first electrode 130, the horizontal second electrode 150, and a part of the vertical word line 160 are disposed.

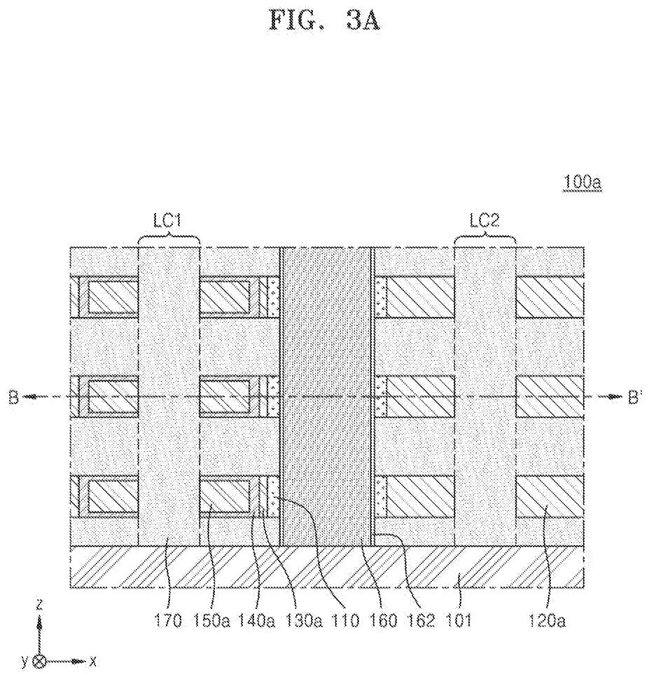

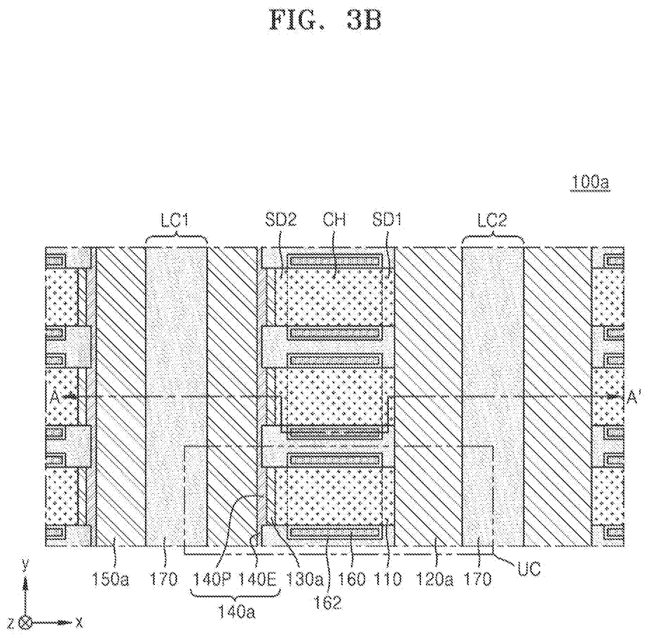

FIGS. 3A and 3B are vertical and horizontal cross-sectional views of a 3D FeRAM according to an embodiment. FIG. 3A is a vertical cross-sectional view of a portion A-A′ of FIG. 3B, and FIG. 3B is a horizontal cross-sectional view of a portion B-B′ of FIG. 3A. FIGS. 3A and 3B are described together with reference to FIG. 1, and the description already provided with reference to FIGS. 1 to 2B is briefly repeated or omitted.

Referring to FIGS. 3A and 3B, a 3D FeRAM 100a may be different from the 3D FeRAM 100 of FIG. 1 in a structure of bit lines 120a, first electrodes 130a, ferroelectric layers 140a, and second electrodes 150a. Specifically, the 3D FeRAM 100a may include the substrate 101, the semiconductor patterns 110, the bit lines 120a, the first electrodes 130a, the ferroelectric layers 140a, the second electrodes 150a, and the word lines 160. Structures and materials of the substrate 101, the semiconductor patterns 110, and the word lines 160 are the same as those described in the description of the 3D FeRAM 100 of FIG. 1.

The bit lines 120a may be spaced apart from each other in the vertical direction (z direction) on the substrate 101 and may be disposed at positions corresponding to the semiconductor patterns 110. In addition, the bit line 120a may be disposed on one side surface of the semiconductor pattern 110 in the first horizontal direction (x direction) and extend in the second horizontal direction (y direction). For example, the semiconductor patterns 110 disposed in the second horizontal direction (y direction) on one layer in the vertical direction (z direction) may be connected together to the bit lines 120a disposed in the corresponding layer.

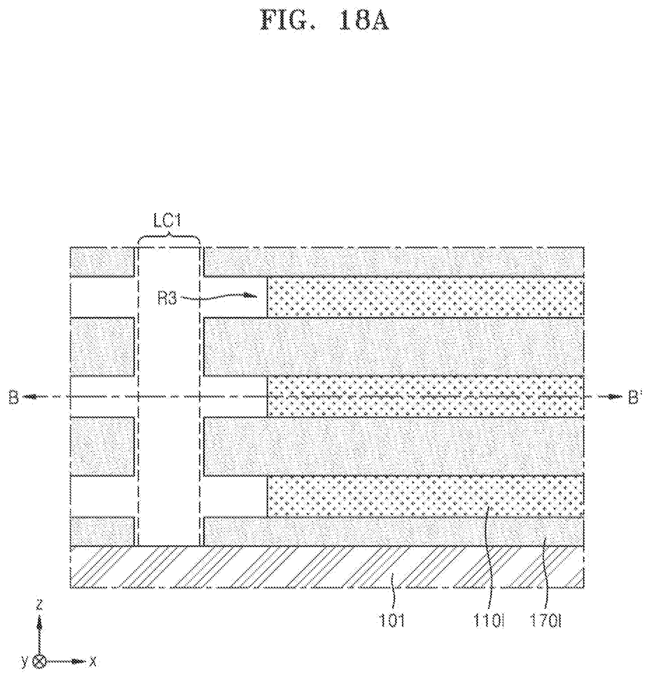

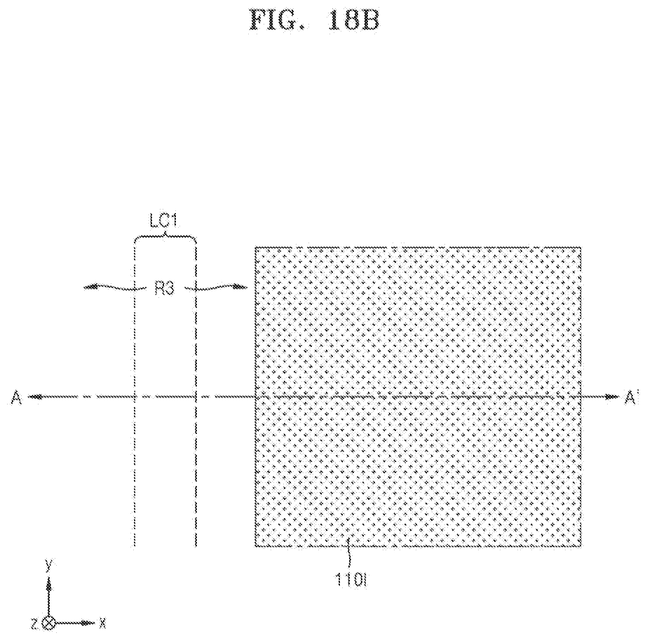

Both sides of the bit line 120a in the first horizontal direction (x direction) may have a straight line shape in the second horizontal direction (y direction). This may be due to the fact that the 3D FeRAM 100a does not include an isolation insulating layer. The structure of the bit line 120a is described in more detail in the description of the manufacturing method of the 3D FeRAM 100a of FIGS. 18A to 24B. The material of the bit line 120a is the same as in the description of the 3D FeRAM 100 of FIG. 1.

The first electrodes 130a may be spaced apart from each other in the vertical direction (z direction) on the substrate 101 and may be disposed at positions corresponding to the semiconductor patterns 110. Also, the first electrodes 130a may be disposed on one side surface of the semiconductor pattern 110 in the first horizontal direction (x direction) and be spaced apart from each other in the second horizontal direction (y direction). For example, the bit line 120a may be disposed on one side surface of the semiconductor pattern 110 in the first horizontal direction (x direction), and the first electrode 130a may be disposed on the other side surface thereof.

The first electrodes 130a may be respectively disposed in and connected to the semiconductor patterns 110. Also, as may be seen from FIGS. 3A and 3B, a horizontal cross-section and a vertical cross-section of the first electrode 130a may have a rectangular shape. Here, the vertical cross-section may indicate a cross-section perpendicular to the second horizontal direction (y direction). Accordingly, the first electrode 130a may have a 3D rectangular pillar shape. The material of the first electrode 130a is the same as in the description of the 3D FeRAM 100 of FIG. 1.

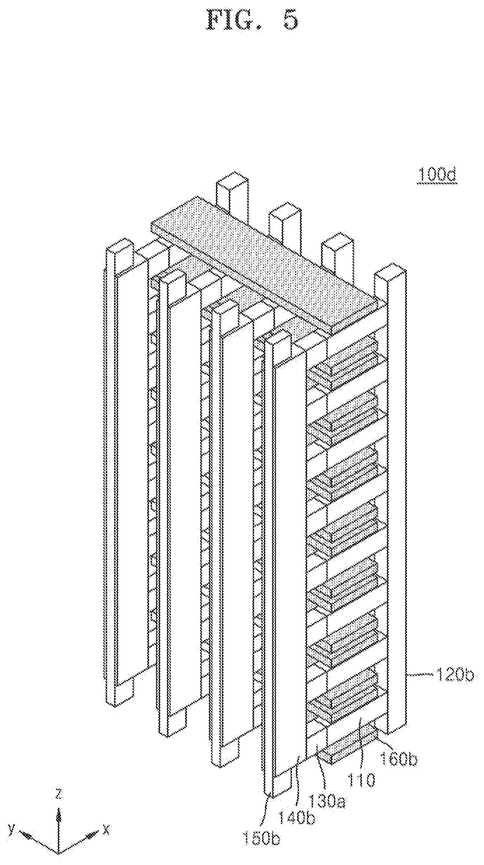

The ferroelectric layers 140a may be spaced apart from each other on the substrate 101 in the vertical direction (z direction) and may extend in the second horizontal direction (y direction). The ferroelectric layer 140a may contact the first electrode 130a at a position corresponding to the semiconductor pattern 110 in the vertical direction (z direction) and the second horizontal direction (y direction). As the ferroelectric layers 140a are spaced apart from each other in the vertical direction (z direction), unlike the structure of the 3D FeRAM 100 of FIG. 1, the ferroelectric layers 140a may be separated from each other in the vertical direction (z direction). This may be similar to a structure in which the ferroelectric layers 140a are separated from each other in the second horizontal direction (y direction) in a 3D FeRAM 100d of FIG. 5.

The ferroelectric layer 140a may include an extension 140E extending in the second horizontal direction (y direction) on a horizontal cross-section, and a protrusion 140P protruding from the extension 140E in the first horizontal direction (x direction) to contact the first electrode 130a on a horizontal cross-section. As shown in FIG. 3A, the ferroelectric layer 140a may have a ‘ [symbol] ’ shape in a vertical cross-section. Here, the vertical cross-section may indicate a cross-section perpendicular to the second horizontal direction (y direction). A material of the ferroelectric layer 140a and a single layer or multilayer structure are the same as those described in the 3D FeRAM 100 of FIG. 1.

The second electrodes 150a may be spaced apart from each other in the vertical direction (z direction) on the substrate 101 and may be disposed at positions corresponding to the semiconductor patterns 110. The second electrode 150a may be disposed on one side surface of the ferroelectric layer 140a in the first horizontal direction (x direction) and extend in the second horizontal direction (y direction). That is, the first electrode 130a may be disposed on one side surface of the ferroelectric layer 140a in the first horizontal direction (x direction) and the second electrode 150a may be disposed on the other side surface thereof.

The second electrode 150a may have a straight strip shape extending in the second horizontal direction (y direction) in the horizontal cross-section. In addition, the second electrode 150a may have a quadrangular shape filling the ‘ [symbol] ’-shaped inside of the ferroelectric layer 140 in the vertical cross-section. A material of the second electrode 150a is the same as in the description of the 3D FeRAM 100 of FIG. 1.

The 3D FeRAM 100a may be different from the 3D FeRAM 100 of FIG. 1 in the structure of the first electrode 130a, the ferroelectric layer 140a, and the second electrode 150a constituting an FeCap. However, the 3D FeRAM 100a may be substantially the same as the 3D FeRAM 100 of FIG. 1 in the circuit connection relationship with the semiconductor pattern 110, except that the ferroelectric layers 140a are not connected to each other in the vertical direction (z direction). Therefore, the 3D FeRAM 100a may have a 1TR1Cap structure, thereby solving an endurance problem and a leakage issue due to use of poly Si. In addition, the 3D FeRAM 100a may have a structure in which the second electrodes 150a are separated from each other in correspondence to the bit lines 120a for each layer in the vertical direction (z direction), thereby solving a read disturb problem. For reference, as may be seen in FIG. 3A, the 3D FeRAM 100a may also have a structure in which in one layer in the vertical direction (z direction), the horizontal channel region CH, the horizontal bit line 120a, the horizontal first electrode 130a, the horizontal second electrode 150a, and a part of the vertical word line 160 are disposed.

FIGS. 4A and 4B are horizontal cross-sectional views of a 3D FeRAM according to an embodiment and respectively correspond to FIGS. 2B and 3B. The description already provided with reference to FIGS. 1 to 3B is briefly repeated or omitted.

Referring to FIG. 4A, a 3D FeRAM 100b may be different from the 3D FeRAM 100 of FIG. 2B in a structure of the word line 160a. Specifically, in the 3D FeRAM 100b, the word line 160a may extend from the substrate 101 in the vertical direction (z direction) and may be disposed in the second horizontal direction (y direction). As may be seen from FIG. 4A, one word line 160a may be disposed between adjacent semiconductor patterns 110 in the second horizontal direction (y direction). Accordingly, the 3D FeRAM 100b may include a single gate transistor in which one word line 160a is disposed in each channel region CH.

Referring to FIG. 4B, a 3D FeRAM 100c may be different from the 3D FeRAM 100a of FIG. 3B in the structure of the word line 160a. Specifically, in the 3D FeRAM 100c, the word line 160a may extend from the substrate 101 in the vertical direction (z direction) and may be disposed in the second horizontal direction (y direction). As may be seen from FIG. 4B, one word line 160a may be disposed between the adjacent semiconductor patterns 110 in the second horizontal direction (y direction). Accordingly, the 3D FeRAM 100c may include a single gate transistor in which one word line 160a is disposed in each channel region CH.

FIG. 5 is a conceptual diagram illustrating a 3D FeRAM according to an embodiment. The description already provided with reference to FIGS. 1 to 4B is briefly repeated or omitted.

Referring to FIG. 5, a 3D FeRAM 100d may be different the 3D FeRAM 100a of FIG. 3A in extension directions of bit lines 120b, ferroelectric layers 140b, second electrodes 150b, and word lines 160b. Specifically, the 3D FeRAM 100d may include the substrate (see 101 in FIG. 3A), the semiconductor patterns 110, the bit lines 120b, the first electrodes 130a, the ferroelectric layers 140b, the second electrodes 150b, and the word lines 160b. Structures and materials of the substrate 101, the semiconductor pattern 110, and the first electrode 130a are the same as those described in the 3D FeRAM 100a of FIG. 3A.

The bit line 120b may extend in the vertical direction (z direction) on the substrate 101. In addition, the bit lines 120b may be spaced apart from each other in the second horizontal direction (y direction) and disposed at positions corresponding to the semiconductor pattern 110. For example, the bit line 120b may be disposed on one side surface of the semiconductor pattern 110 in the first horizontal direction (x direction), and in a column in the second horizontal direction (y direction), the semiconductor patterns 110 disposed in the vertical direction (z direction) may be connected together to the bit lines 120b disposed in the corresponding column.

The ferroelectric layers 140b may be disposed spaced apart from each other in the second horizontal direction (y direction) on the substrate 101 and may extend in the vertical direction (z direction). The ferroelectric layer 140b may contact the first electrode 130a at a position corresponding to the semiconductor pattern 110 in the vertical direction (z direction) and the second horizontal direction (y direction). As the ferroelectric layers 140b are spaced apart from each other in the second horizontal direction (y direction), the ferroelectric layers 140b may be separated from each other in the second horizontal direction (y direction).

A specific structure of the ferroelectric layer 140b may be substantially the same as that of the ferroelectric layer 140a of the 3D FeRAM 100a of FIG. 3A, except for a direction in which the ferroelectric layer 140b extends. Accordingly, the ferroelectric layer 140b may include an extension extending in the vertical direction (z direction) on a vertical cross-section, and a protrusion protruding in the first horizontal direction (x direction) from the extension and contacting the first electrode 130a on a vertical cross-section. Also, the ferroelectric layer 140b may have a ‘ [symbol] ’ shape on a horizontal cross-section. Here, the vertical cross-section may indicate a cross-section perpendicular to the second horizontal direction (y direction). A material of the ferroelectric layer 140b and a single layer or multilayer structure are the same as in the description of the 3D FeRAM 100 of FIG. 1.

In addition, the ferroelectric layer 140b may have a structure of the ferroelectric layer 140 of the 3D FeRAM 100 of FIG. 1. That is, the ferroelectric layer 140b may have a structure extending in each of the vertical direction (z direction) and the second horizontal direction (y direction). In such a structure, the first electrode 130a may have the structure of the first electrode 130 of the 3D FeRAM 100 of FIG. 1.

The second electrode 150b may extend from the substrate 101 in the vertical direction (z direction). In addition, the second electrodes 150b may be spaced apart from each other in the second horizontal direction (y direction) and may be disposed at positions corresponding to the semiconductor patterns 110. The second electrode 150b may be disposed on one side surface of the ferroelectric layer 140b in the first horizontal direction (x direction). That is, the first electrode 130a may be disposed on one side surface of the ferroelectric layer 140b in the first horizontal direction (x direction) and the second electrode 150b may be disposed on the other side surface thereof.

A specific structure of the second electrode 150b may be substantially the same as that of the second electrode 150a of the 3D FeRAM 100a of FIG. 3A, except for a direction in which the second electrode 150b extends. Accordingly, the second electrode 150b may have a straight strip shape extending in the vertical direction (z direction) on the vertical cross-section. In addition, the second electrode 150b may have a rectangular shape filling the ‘ [symbol] ’-shaped inside of the ferroelectric layer 140b on the horizontal cross-section. Here, the vertical cross-section may indicate a cross-section perpendicular to the second horizontal direction (y direction). A material of the second electrode 150b is the same as in the description of the 3D FeRAM 100 of FIG. 1.

The word lines 160b may be spaced apart from each other in the vertical direction (z direction) on the substrate 101 and may extend in the second horizontal direction (y direction). As may be seen from FIG. 5, two word lines 160b may be disposed between adjacent semiconductor patterns 110 in the vertical direction (z direction). However, according to an embodiment, one word line 160b may be disposed between the adjacent semiconductor patterns 110 in the vertical direction (z direction).

A comparison between the 3D FeRAM 100d and the 3D FeRAM 100a of FIG. 3A is as follows. In the 3D FeRAM 100a of FIG. 3A, the bit line 120a, the ferroelectric layer 140a, and the second electrode 150a may extend in the second horizontal direction (y direction) on the substrate 101, and the word line 160 may extend in the vertical direction (z direction) on the substrate 101. In contrast, in the 3D FeRAM 100d, the word line 160b may extend in the second horizontal direction (y direction) on the substrate 101, and the bit line 120b, the ferroelectric layer 140b, and the second electrode 150b may extend in the vertical direction (z direction) on the substrate 101. As described above, the 3D FeRAM 100d may be substantially the same as the 3D FeRAM 100a of FIG. 3A in a circuit connection relationship, except for extension directions of the bit line 120b, the ferroelectric layer 140b, and the second electrode 150b. Accordingly, the 3D FeRAM 100d may have substantially the same advantages as the 3D FeRAM 100a of FIG. 3A.

FIGS. 6A to 16B are vertical and horizontal cross-sectional views illustrating a process of manufacturing the 3D FeRAM of FIGS. 2A and 2B. FIGS. 6A, 7A, 8A, 9A, 10A, 11A, 12A, 13A, 14A, 15A and 16A are vertical cross-sectional views corresponding to FIG. 2A, and FIGS. 6B, 7B, 8B, 9B, 10B, 11B, 12B, 13B, 14B, 15B and 16B are horizontal cross-sectional views corresponding to FIG. 2B. FIGS. 6A to 16B are described with reference to FIGS. 1 to 2B, and the description already provided with reference to FIGS. 1 to 2B is briefly repeated or omitted.

Referring to FIGS. 6A and 6B, in the manufacturing method of the 3D FeRAM, first, first insulating layers 1701 and semiconductor layers 1101 are alternately stacked on the substrate 101. The first insulating layer 1701 may include, for example, silicon oxide, and the semiconductor layer 1101 may include, for example, poly Si. However, the first insulating layer 1701 and the semiconductor layer 1101 are not limited to the above materials. Hereinafter, the first insulating layers 1701 and the semiconductor layers 1101 stacked on the substrate 101 are referred to as a ‘stacked structure’.

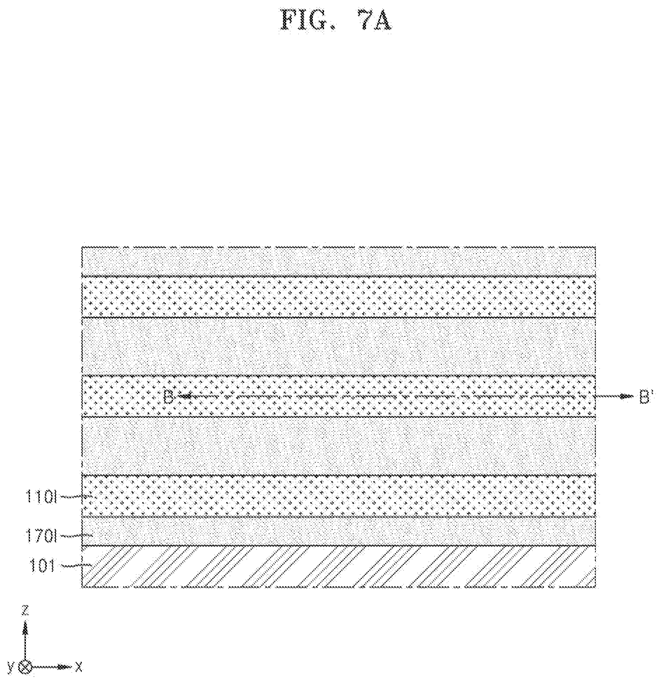

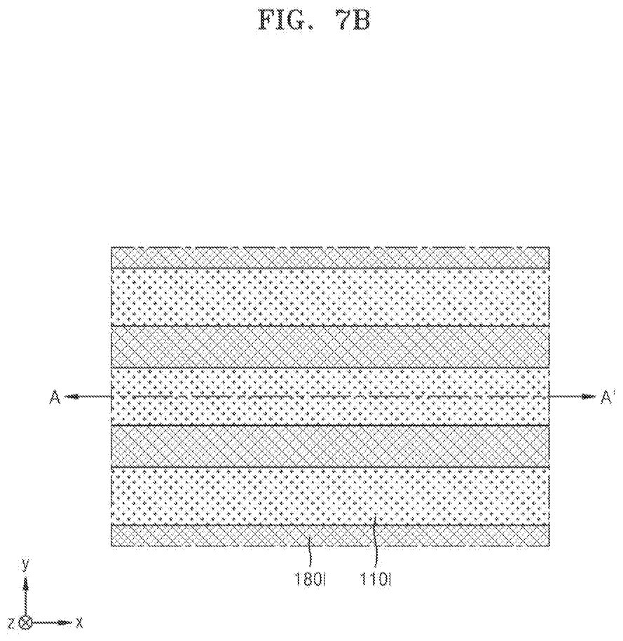

Referring to FIGS. 7A and 7B, trenches penetrating the stacked structure, extending in the vertical direction (z direction) and the first horizontal direction (x direction), and spaced apart from each other in the second horizontal direction (y direction) are formed. An upper surface of the substrate 101 may be exposed through an inner bottom surface of the trench. In addition, the first insulating layers 1701 and the semiconductor layers 1101, which are alternately stacked, may be exposed through an inner side surface of the trench. After the trench is formed, the trench is filled with a second insulating layer 1801. The semiconductor layers 1101 may be separated from each other in the second horizontal direction (y direction) by the second insulating layers 1801. In addition, the stacked structure may include the second insulating layer 1801.

The second insulating layer 1801 may have a different etching rate from that of the first insulating layer 1701. For example, with respect to an etchant that etches the semiconductor layer 1101, the etching rate of the second insulating layer 1801 may be higher than that of the first insulating layer 1701. Specifically, with respect to the etchant that etches the semiconductor layer 1101, the etching rate of the semiconductor layer 1101 is the highest, the etching rate of the second insulating layer 1801 is the second highest, and the etching rate of the first insulating layer 1701 may have the lowest. When the semiconductor layer 1101 includes poly Si and the first insulating layer 1701 includes oxide, the second insulating layer 1801 may include nitride. However, materials of the semiconductor layer 1101, the first insulating layer 1701, and the second insulating layer 1801 are not limited to the above materials.

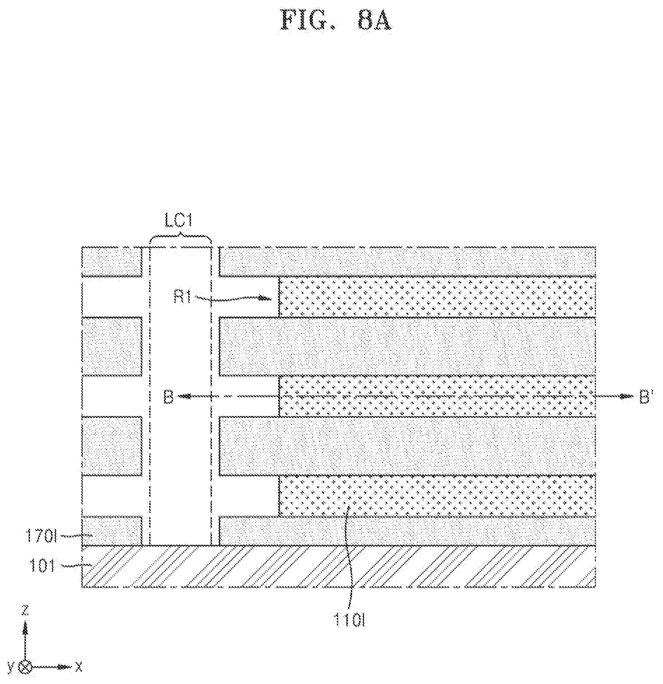

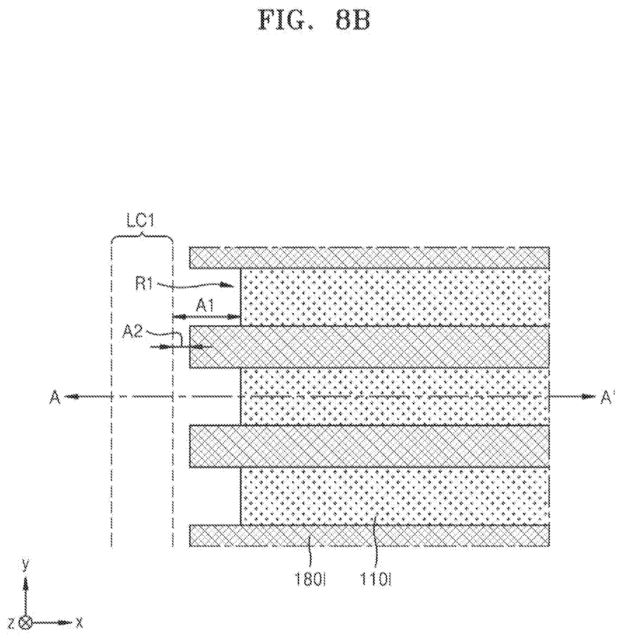

Referring to FIGS. 8A and 8B, after the second insulating layer 1801 is formed, the first line cut LC1 penetrating the stacked structure and extending in the vertical direction (z direction) and the second horizontal direction (y direction) is formed. The upper surface of the substrate 101 may be exposed through an inner bottom surface of the first line cut LC1, and the first insulating layer 1701 and the second insulating layer 1801, and the semiconductor layer 1101, which are alternately stacked, may be exposed through an inner side surface of the first line cut LC1. After the first line cut LC1 is formed, a first recess R1 is formed in the first horizontal direction (x direction) by etching the semiconductor layer 1101 exposed through the inner side surface of the first line cut LC1.

As described above, the etching rate of the first insulating layer 1701 is lower than that of the second insulating layer 1801, and accordingly, when the semiconductor layer 1101 is etched, the second insulating layer 1801 may be slightly etched. However, the first insulating layer 1701 may hardly be etched. Accordingly, when the semiconductor layer 1101 is etched by a first thickness A1 in the first horizontal direction (x direction) from the first line cut LC1 indicated by a dotted line in FIG. 8B, the second insulating layer 1801 may be etched by a second thickness A2, which is less than the first thickness A1. The first insulating layer 1701 may be etched to a very fine thickness or hardly etched in the first horizontal direction (x direction) from the first line cut LC1. For example, the first insulating layer 1701 may be etched by a third thickness which is less than the second thickness A2.

After the first recess R1 is formed, a junction may be formed by doping a side portion of the semiconductor layer 1101 exposed through the first recess R1 with impurities. In addition, a silicide layer may be formed by performing a silicide process for ohmic contact with a metal layer, for example, the first electrode 130.

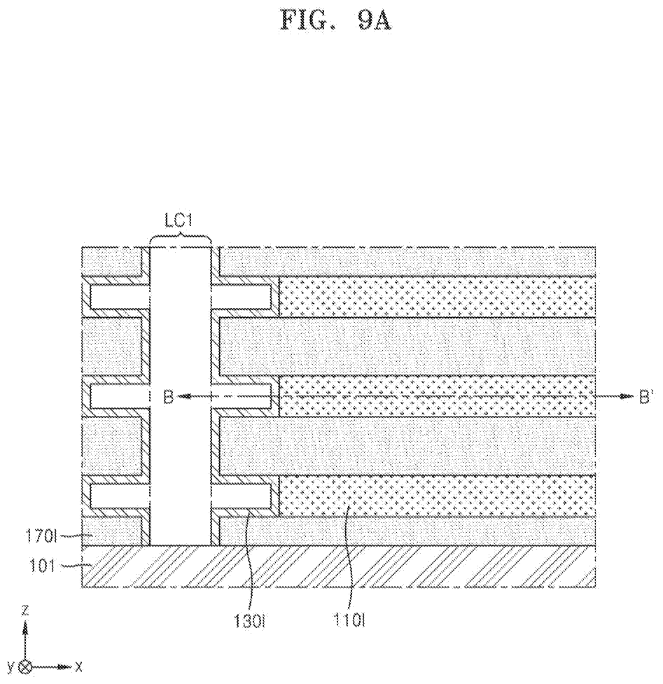

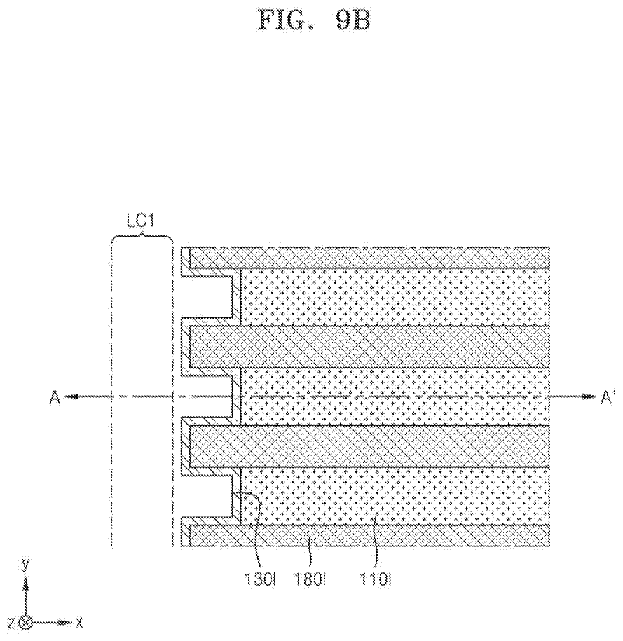

Referring to FIGS. 9A and 9B, a first electrode material layer 1301 is formed on the semiconductor layer 1101, the first insulating layer 1701, and the second insulating layer 1801 exposed through the first line cut LC1 and the first recess R1. The first electrode material layer 1301 may be formed as thin as several tens to hundreds of nm. However, a thickness of the first electrode material layer 1301 is not limited to the above numerical range. As shown in FIGS. 9A and 9B, the first electrode material layer 1301 may include a ‘ [symbol] ’ shaped portion on a horizontal cross-section and a vertical cross-section.

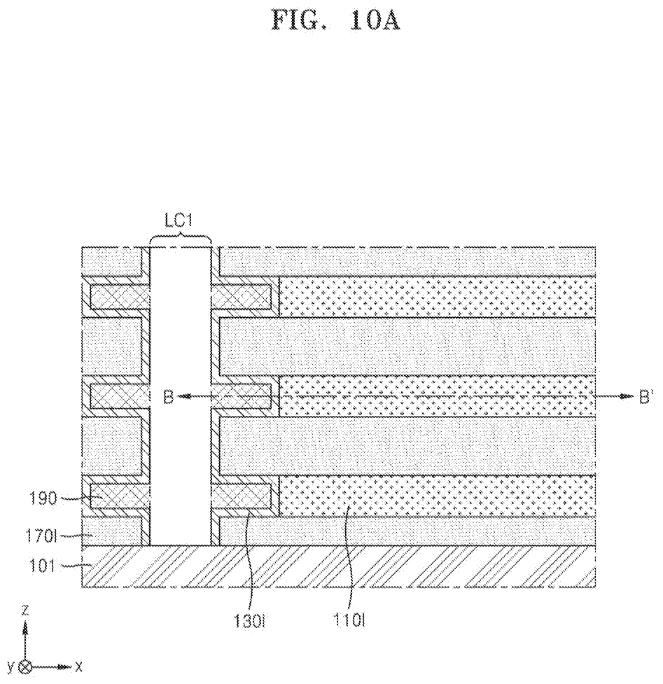

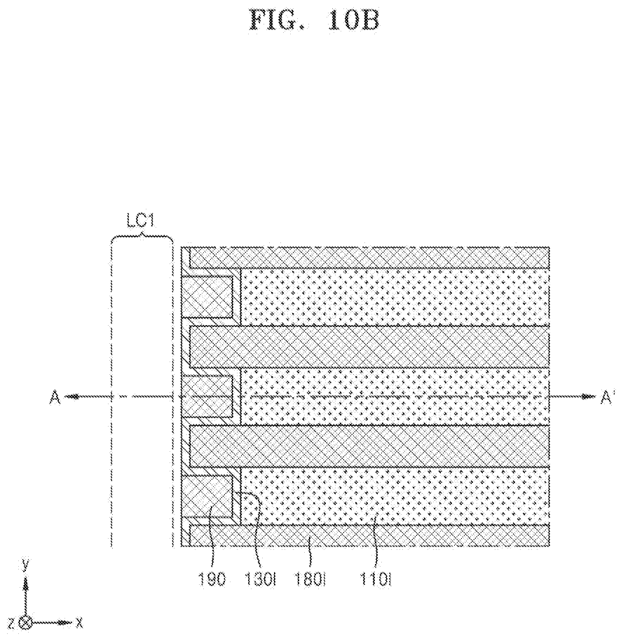

Referring to FIGS. 10A and 10B, after the first electrode material layer 1301 is formed, third insulating layers 190 filling the ‘ [symbol] ’-shaped portion of the first electrode material layer 1301 are formed. The third insulating layer 190 may be formed by allowing an insulating material to remain only in the ‘ [symbol] ’-shaped portion through an anisotropic etching process after filling both the ‘ [symbol] ’-shaped portion of the first electrode material layer 1301 and the first line cut LC1 with the insulating material. The third insulating layer 190 may be formed to protect the ‘ [symbol] ’-shaped portion of the first electrode material layer 1301 in a node separation process of the first electrode material layer 1301. The third insulating layer 190 may include a material having an etching rate that is different from that of each of the first insulating layer 1701 and the second insulating layer 1801.

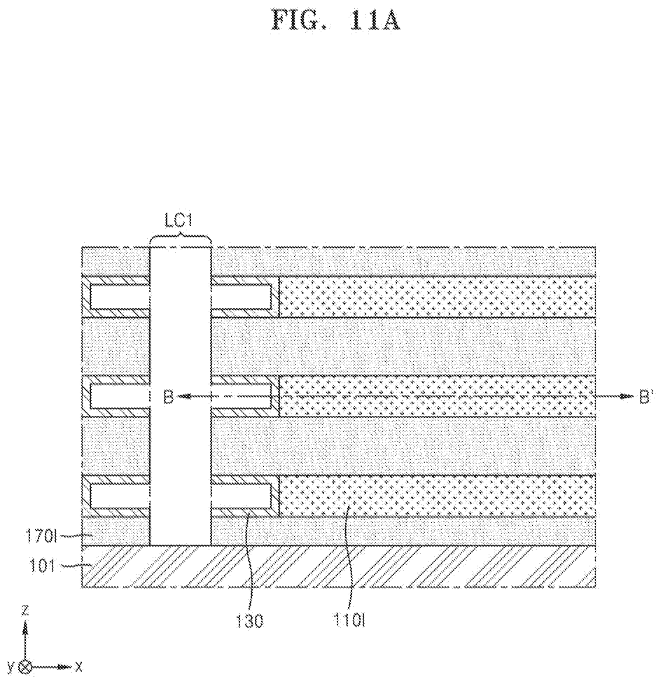

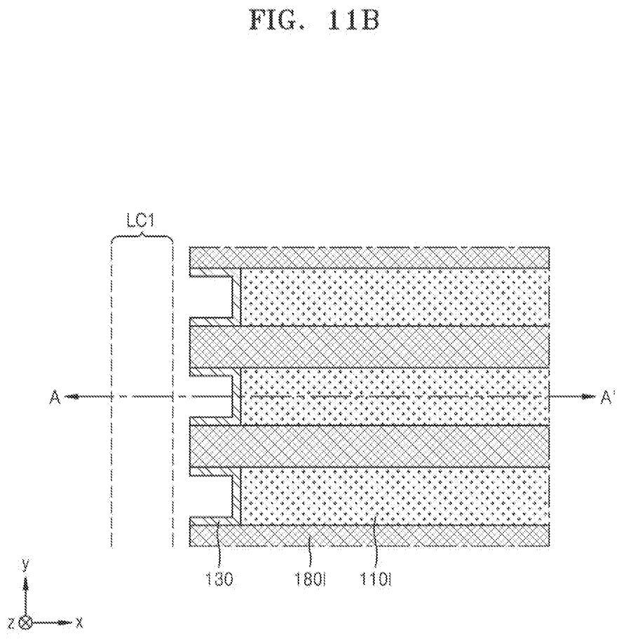

Referring to FIGS. 11A and 11B, the node separation process of the first electrode material layer 1301 is performed. Through the node separation process, the first electrode material layers 1301 are separated from each other in the vertical direction (z direction) and the second horizontal direction (y direction), and thus, the first electrode 130 may be formed. The node separation process may be performed by etching the first electrode material layer 1301 exposed through the first line cut LC1. As described above, in the node separation process, because the ‘ [symbol] ’-shaped portion of the first electrode material layer 1301 is covered by the third insulating layer 190, the ‘ [symbol] ’-shaped portion may remain without being etched. After the first electrode 130 is formed, the third insulating layer 190 may be removed.

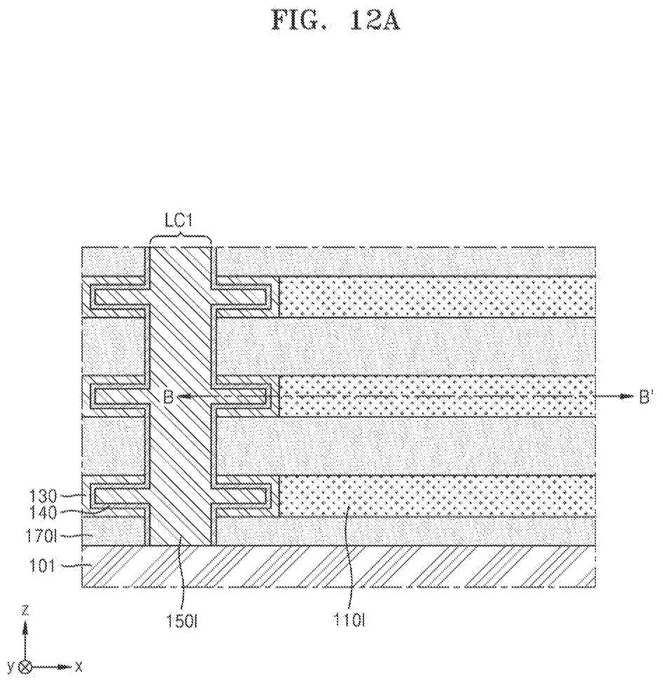

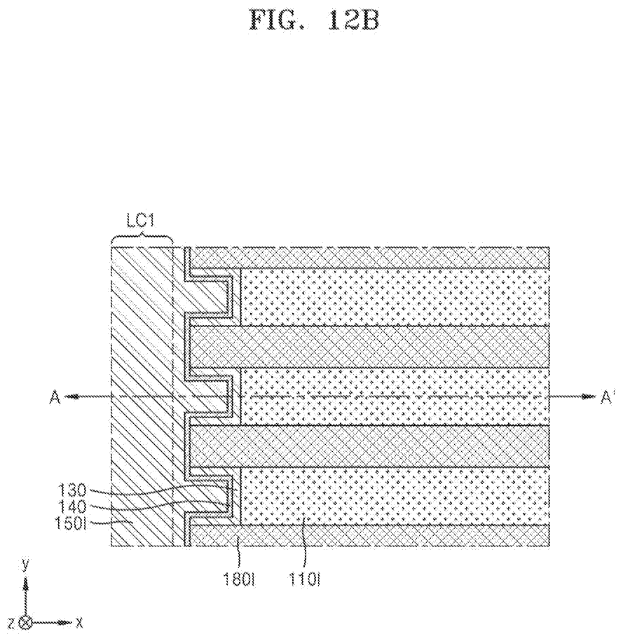

Referring to FIGS. 12A and 12B, after the first electrode 130 is formed, the ferroelectric layer 140 and a second electrode material layer 1501 are sequentially formed on the first electrode 130. According to an embodiment, the ferroelectric layer 140 may have a multilayer structure. For example, the ferroelectric layer 140 may have a triple layer structure of a first ferroelectric thin film, an AlO thin film, and a second ferroelectric thin film or a five layer structure of the first ferroelectric thin film, a first AlO thin film, the second ferroelectric thin film, a second AlO thin film, and a third ferroelectric thin film. However, a multilayer structure of the ferroelectric layer 140 is not limited to the triple layer or five layer structure.

As shown in FIGS. 12A and 12B, the second electrode material layer 1501 may fill both a ‘ [symbol] ’-shaped portion of the ferroelectric layer 140 and the first line cut LC1. However, according to an embodiment, the second electrode material layer 1501 may be formed to a certain thickness on a sidewall and a bottom surface of the first line cut LC1 by filling entirely the ‘ [symbol] ’ shaped portion of the ferroelectric layer 140 but partially filling the first line cut LC1.

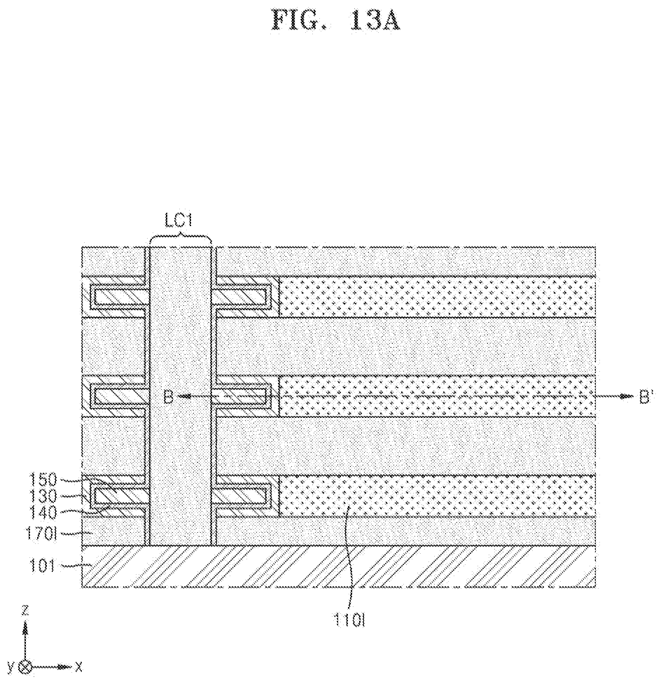

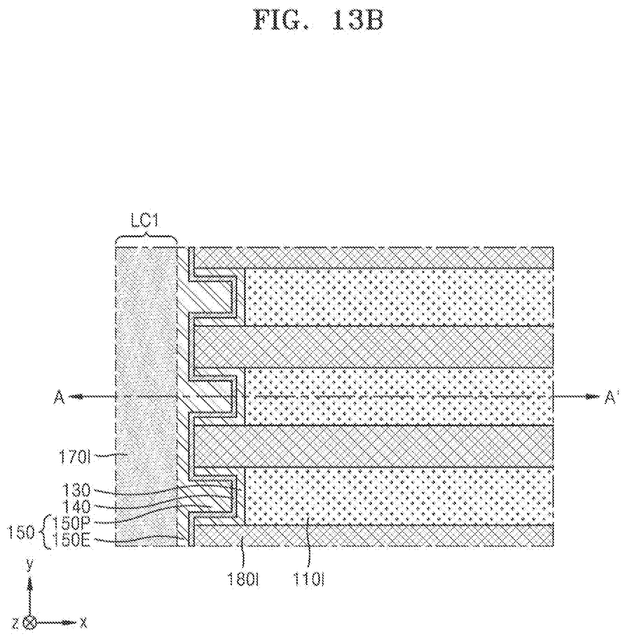

Referring to FIGS. 13A and 13B, after the second electrode material layer 1501 is formed, the second electrode 150 is formed by re-etching the first line cut LC1 and separating the second electrode material layers 1501 from each other in the vertical direction (z direction). By re-etching the first line cut LC1, as shown in FIG. 13A, the second electrodes 150 may be spaced apart from each other in the vertical direction (z direction). In addition, as shown in FIG. 13B, the second electrode 150 may include the extension 150E extending in the second horizontal direction (y direction) on the horizontal cross-section and the protrusion 150P protruding from the extension 150E in the first horizontal direction (x direction on the horizontal cross-section. After the second electrode 150 is formed, the first line cut LC1 may be filled with the first insulating layer 1701.

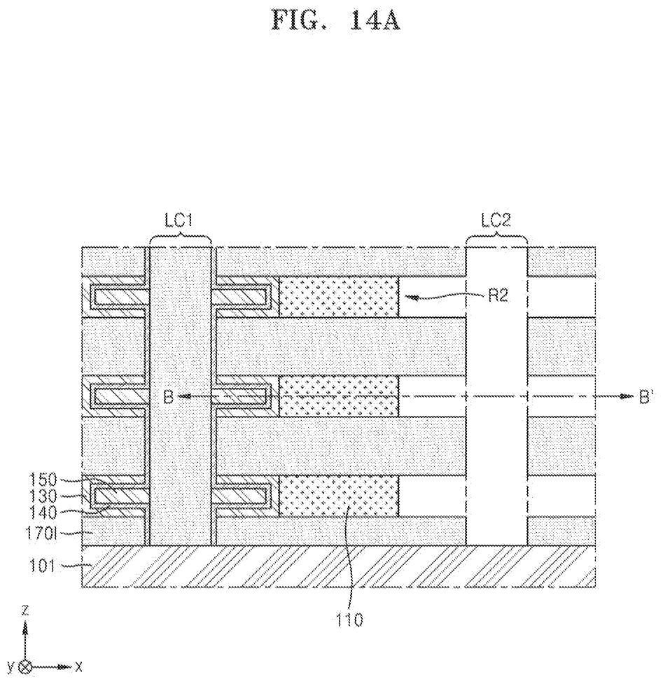

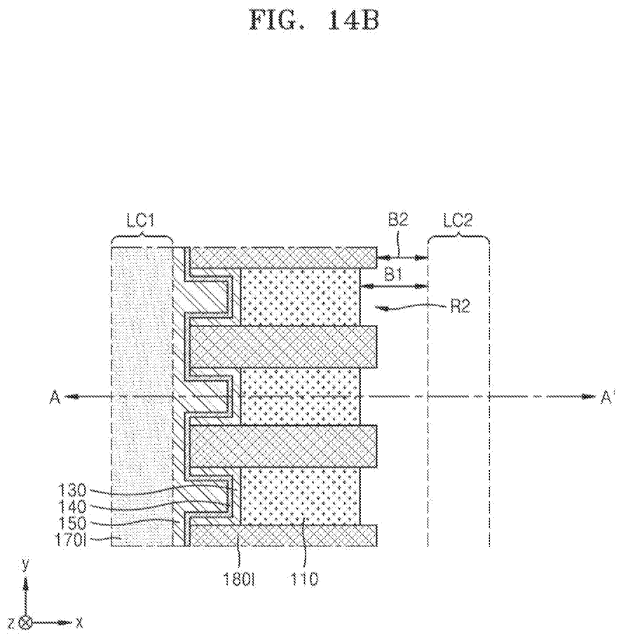

Referring to FIGS. 14A and 14B, thereafter, at a position opposite to the first line cut LC1 in the first horizontal direction (x direction) with respect to the semiconductor layer 1101, the second line cut LC2 penetrating the stacked structure and extending in the second horizontal direction (y direction) and the vertical direction (z direction) is formed. An upper surface of the substrate 101 may be exposed through an inner bottom surface of the second line cut LC2, and the first insulating layer 1701, the second insulating layer 1801, and the semiconductor layer 1101 may be exposed through an inner side surface of the second line cut LC2. After the second line cut LC2 is formed, a second recess R2 is formed in the first horizontal direction (x direction) by etching the semiconductor layer 1101 exposed through the inner side surface of the second line cut LC2. The semiconductor pattern 110 may be formed through the formation of the second recess R2.

As described above, with respect to the etching etchant of the semiconductor layer 1101, the etching rate of the first insulating layer 1701 is lower than that of the second insulating layer 1801, and accordingly, when the semiconductor layer 1101 is etched, the second insulating layer 1801 may be slightly etched. However, the first insulating layer 1701 may hardly be etched. Accordingly, when the semiconductor layer 1101 is etched by a first thickness B1 in the first horizontal direction (x direction) from the second line cut LC2 indicated by a dotted line in FIG. 14B, the second insulating layer 1801 may be etched by a second thickness B2, which is less than the first thickness B1.

After the second recess R2 is formed, a junction may be formed by doping a side portion of the semiconductor pattern 110 exposed through the second recess R2 with impurities. In addition, a silicide layer may be formed by performing a silicide process for ohmic contact with a metal layer, for example, the bit line 120.

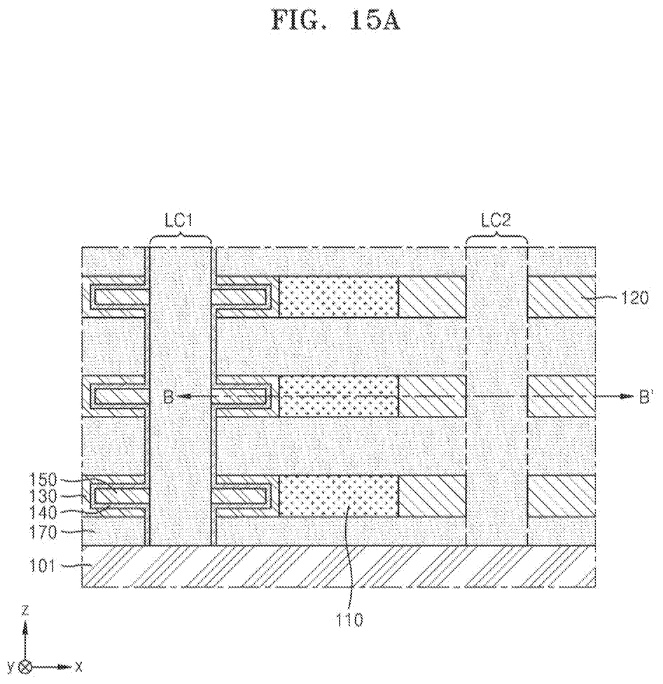

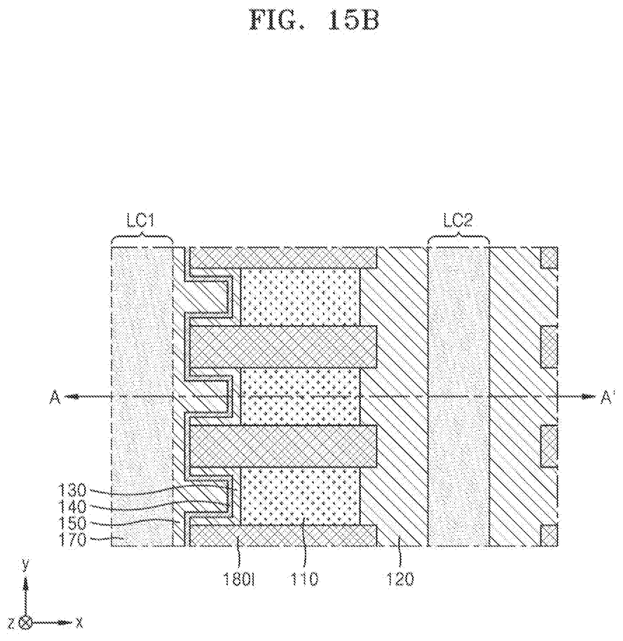

Referring to FIGS. 15A and 15B, the bit line 120 is formed on the semiconductor pattern 110, the first insulating layer 1701, and the second insulating layer 1801 exposed through the second line cut LC2 and the second recess R2. More specifically, first, a bit line material layer filling the second line cut LC2 and the second recess R2 is formed. Thereafter, the bit line 120 is formed by re-etching the second line cut LC2 and separating the bit line material layers from each other in the vertical direction (z direction). As shown in FIG. 15A, the bit lines 120 may be spaced apart from each other in the vertical direction (z direction). In addition, as shown in FIG. 15B, a side portion of the bit line 120 extending in the second horizontal direction (y direction) and contacting the semiconductor pattern 110 in the first horizontal direction (x direction) may have a concave-convex shape, and an opposite side portion thereof may have a straight line shape. The concave-convex shape of the side portion of the bit line 120 may be caused by etching a part of the second insulating layer 1801 during the etching of the semiconductor layer 1101. After the bit line 120 is formed, the interlayer insulating layer 170 may be formed by filling the second line cut LC2 with the first insulating layer 1701.

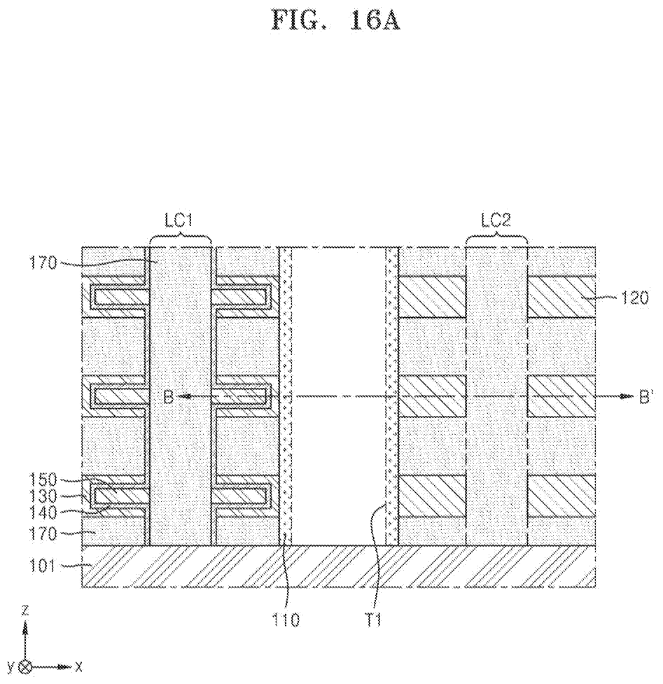

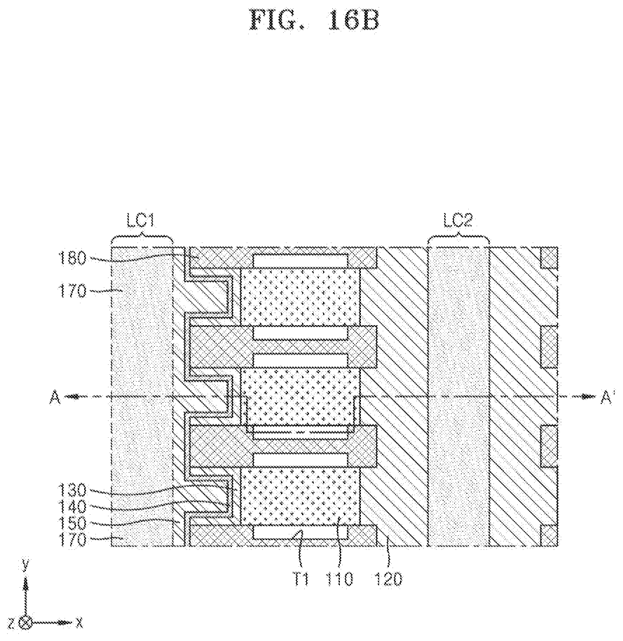

Referring to FIGS. 16A and 16B, a first trench T1 is formed between adjacent semiconductor patterns 110 in the second horizontal direction (y direction). The first trench T1 may penetrate the second insulating layer 1801, extend in the vertical direction (z direction), and expose the upper surface of the substrate 101 through an inner bottom surface thereof. The isolation insulating layer 180 may be formed through the formation of the first trench T1.

As shown in FIG. 16B, two first trenches T1 may be formed between the adjacent semiconductor patterns 110 in the second horizontal direction (y direction). However, according to an embodiment, one first trench T1 may be formed between the adjacent semiconductor patterns 110 in the second horizontal direction (y direction). After the first trench T1 is formed, the word line 160 may be formed by filling the first trench T1 with the gate dielectric layer 162 and a conductive layer.

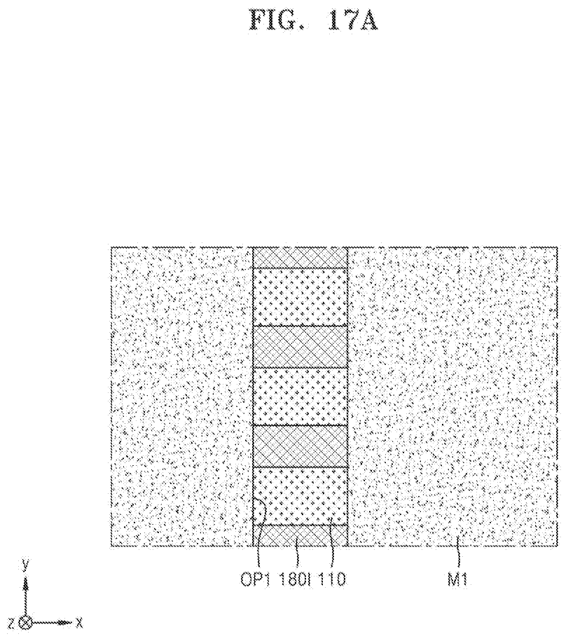

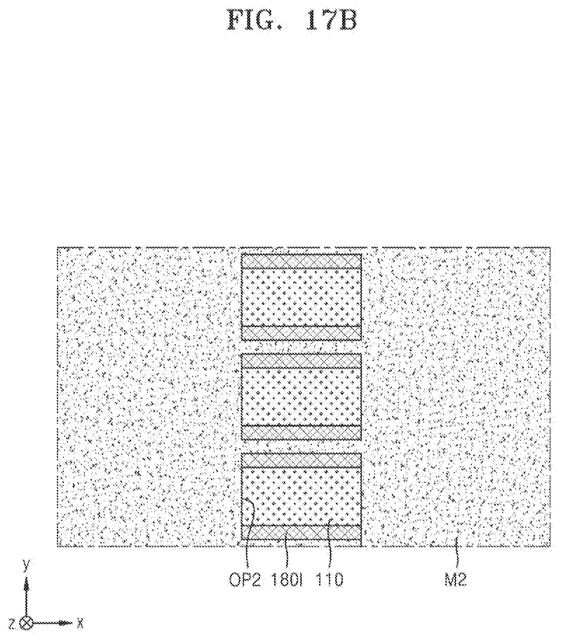

FIGS. 17A and 17B are plan views illustrating a mask structure for forming the word line 160a of the 3D FeRAM of FIG. 4A or 4B and a mask structure for forming the word line 160 of the FeRAM of FIG. 2B or 3B, respectively.

Referring to FIG. 17A, to form the word line 160a as shown in FIG. 4A or 4B, when the first trench T1 is formed, a first mask M1 may be used. The first mask M1 may have a first open portion OP1 extending in the second horizontal direction (y direction), and the semiconductor pattern 110 and the second insulating layer 1801 may be partially exposed through the first open portion OP1. Thereafter, one first trench T1 may be formed between the adjacent semiconductor patterns 110 in the second horizontal direction (y direction) by removing only the second insulating layer 1801 by using the difference in the etching rate between the semiconductor pattern 110 and the second insulating layer 1801. Thereafter, the word line 160a as shown in FIG. 4A or 4B may be formed by filling the first trench T1 with the gate dielectric layer 162 and a conductive layer.

Referring to FIG. 17B, to form the word line 160 as shown in FIG. 2B or 3B, when the first trench T1 is formed, a second mask M2 may be used. The second mask M2 may have a second open portion OP2 in a rectangular shape, and the semiconductor pattern 110 and a part of the second insulating layer 1801 on both sides of the semiconductor pattern 110 in the second horizontal direction (y direction) may be exposed through the second open portion OP2. Thereafter, two first trenches T1 may be formed between the adjacent semiconductor patterns 110 in the second horizontal direction (y direction) by removing only a part of the second insulating layer 1801 by using the difference in the etching rate between the semiconductor pattern 110 and the second insulating layer 1801. Thereafter, the word line 160 as shown in FIG. 2B or 3B may be formed by filling the first trench T1 with the gate dielectric layer 162 and a conductive layer.

FIGS. 18A to 24B are vertical and horizontal cross-sectional views illustrating a process of manufacturing the 3D FeRAM of FIGS. 3A and 3B. FIGS. 18A, 19A, 20A, 21A, 22A, 23A and 24A are vertical cross-sectional views corresponding to FIG. 3A, and FIGS. 18B, 19A, 20B, 21B, 22B, 23B and 24B are horizontal cross-sectional views corresponding to FIG. 3B. FIGS. 18A to 24B are described together with reference to FIGS. 1, 3A, and 3B, and the description already provided with reference to FIGS. 1, 3A, and 3B is briefly repeated or omitted.

Referring to FIGS. 18A and 18B, in the manufacturing method of 3D FeRAM, first, the first insulating layers 1701 and the semiconductor layers 1101 are alternately stacked on the substrate 101. The first insulating layer 1701 may include, for example, silicon oxide, and the semiconductor layer 1101 may include, for example, poly Si. However, the first insulating layer 1701 and the semiconductor layer 1101 are not limited to the above materials. Hereinafter, the first insulating layers 1701 and the semiconductor layers 1101 stacked on the substrate 101 are referred to as a ‘stacked structure’.

Subsequently, the first line cut LC1 penetrating the stacked structure and extending in the vertical direction (z direction) and the second horizontal direction (y direction) is formed. An upper surface of the substrate 101 may be exposed through an inner bottom surface of the first line cut LC1, and the first insulating layers 1701 and the semiconductor layers 1101, which are alternately stacked, may be exposed through an inner side surface of the first line cut LC1. After the first line cut LC1 is formed, a third recess R3 is formed in the first horizontal direction (x direction) by etching the semiconductor layer 1101 exposed through an inner side surface of the first line cut LC1.

After the third recess R3 is formed, a junction may be formed by doping a side portion of the semiconductor layer 1101 exposed through the third recess R3 with impurities. In addition, a silicide layer may be formed by performing a silicide process for ohmic contact with the first electrode 130a.

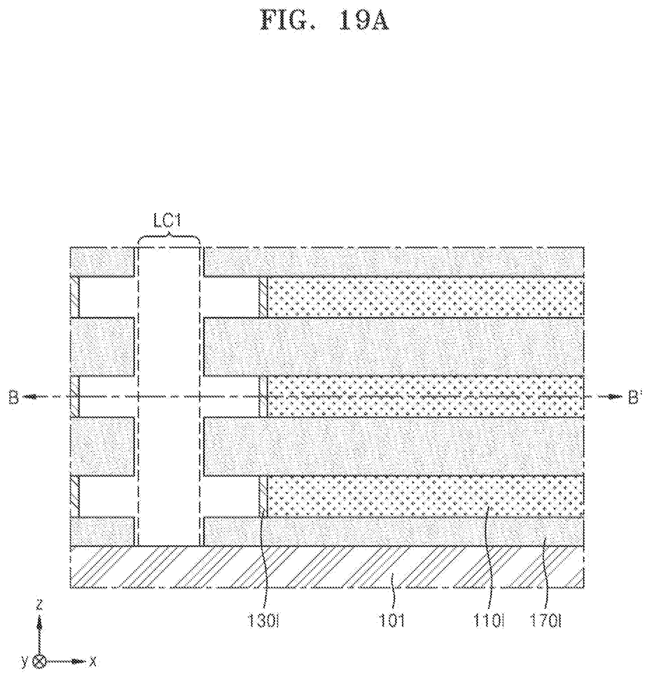

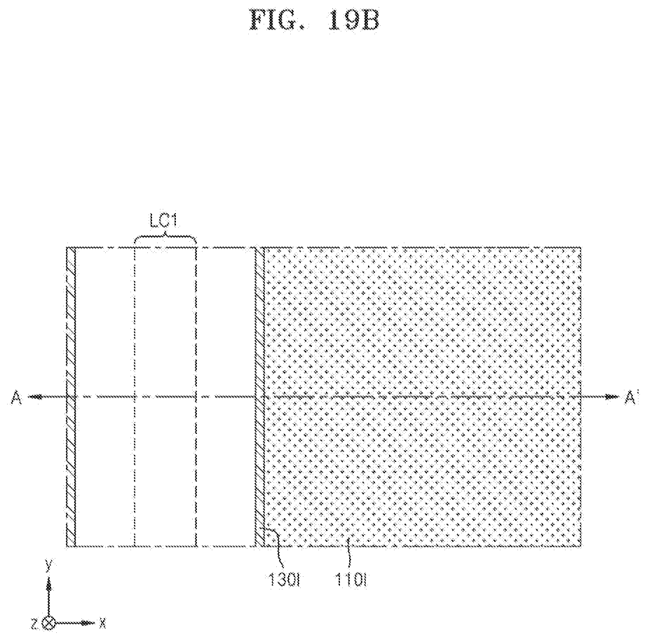

Referring to FIGS. 19A and 19B, the first electrode material layer 1301 is formed on an inner portion of the third recess R3. The first electrode material layer 1301 may be formed by forming an electrode material to fill the third recess R3, and then, forming a recess again by etching a part of the electrode material, and leaving a part of the electrode material inside the recess. The first electrode material layers 1301 may extend in the second horizontal direction (y direction) and be spaced apart from each other in the vertical direction (z direction).

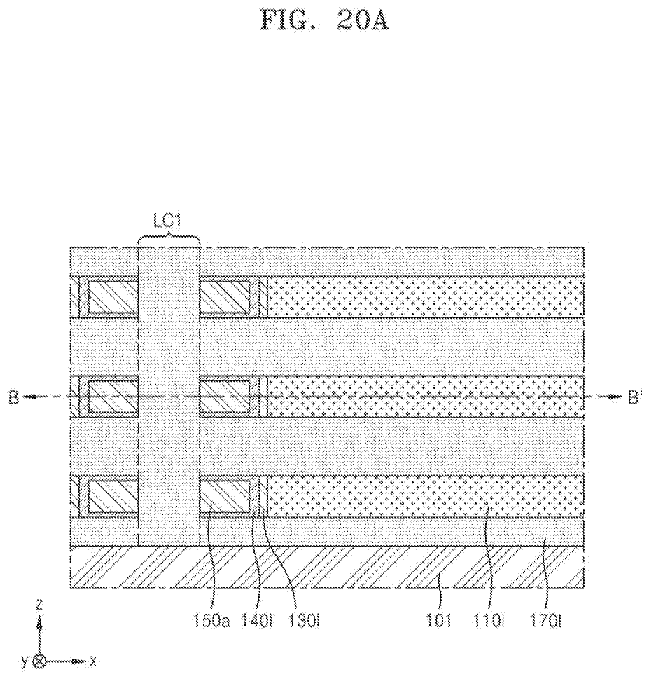

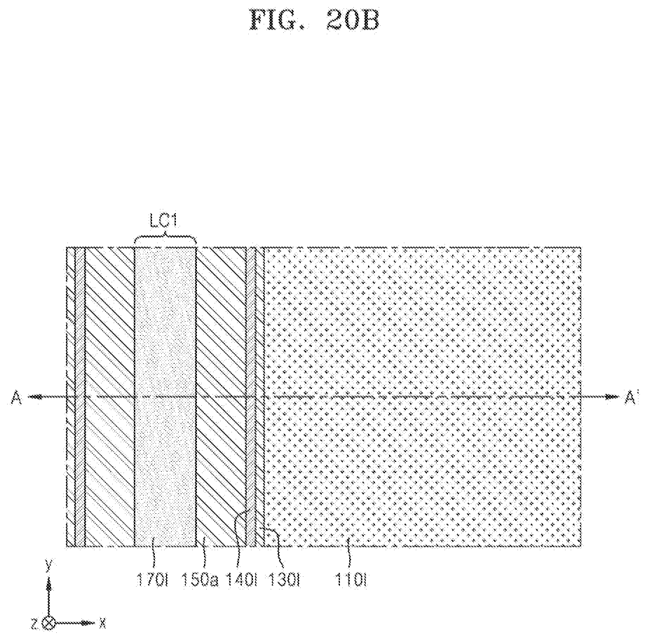

Referring to FIGS. 20A and 20B, after the first electrode material layer 1301 is formed, the ferroelectric material layer 1401 and the second electrode 150a are formed on the first electrode material layer 1301. The ferroelectric material layer 1401 and the second electrode 150a may be formed by sequentially forming ferroelectric materials and electrode materials on the first electrode material layer 1301, separating the ferroelectric materials from each other, and separating the electrode materials from each other in the vertical direction (z direction) by re-etching the first line cut LC1.

The ferroelectric material layers 1401 may be spaced apart from each other in the vertical direction (z direction) and may extend in the second horizontal direction (y direction). In addition, the ferroelectric material layer 1401 may have a straight band shape extending in the second horizontal direction (y direction) on a horizontal cross-section, and may have a ‘ [symbol] ’ shape on a vertical cross-section. The second electrodes 150a may be spaced apart from each other in the vertical direction (z direction) and may extend in the second horizontal direction (y direction). In addition, the second electrode 150a may have a straight band shape extending in the second horizontal direction (y direction) on the horizontal cross-section, and may have a quadrangular shape filling a ‘ [symbol] ’ shaped inside of the ferroelectric material layer 1401 on the vertical cross-section. After the ferroelectric material layer 1401 and the second electrode 150a are formed, the first line cut LC1 may be filled with the first insulating layer 1701.

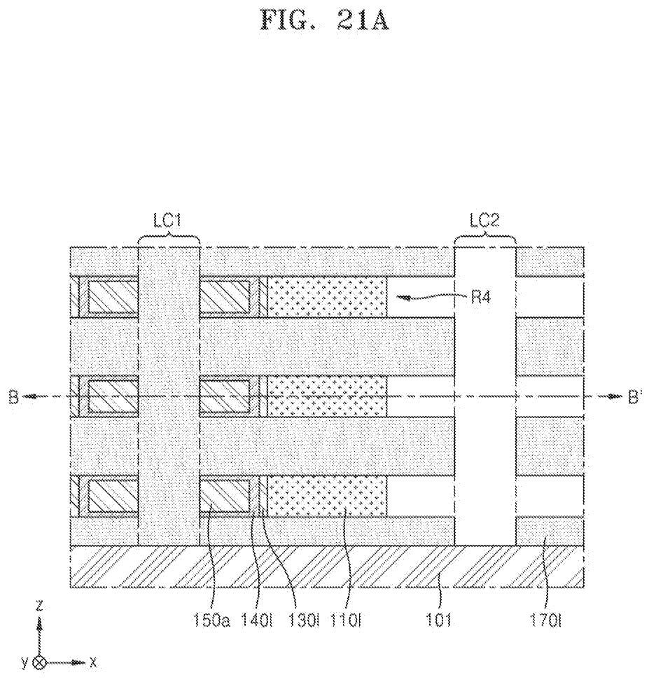

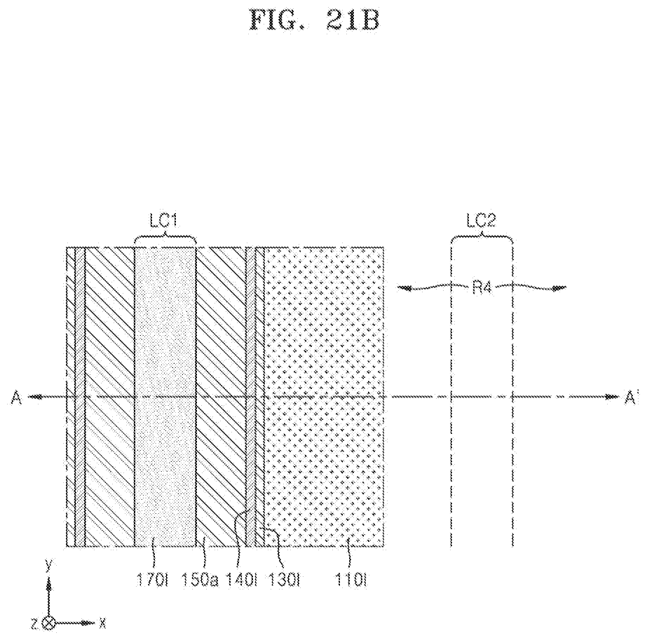

Referring to FIGS. 21A and 21B, the second line cut LC2 penetrating the stacked structure and extending in the vertical direction (z direction) and the second horizontal direction (y direction) is formed. An upper surface of the substrate 101 may be exposed through an inner bottom surface of the second line cut LC2, and the first insulating layer 1701 and the semiconductor layer 1101 may be exposed through an inner side surface of the second line cut LC2. After the second line cut LC2 is formed, a fourth recess R4 is formed in the first horizontal direction (x direction) by etching the semiconductor layer 1101 exposed through the inner side surface of the second line cut LC2.

After the fourth recess R4 is formed, a junction may be formed by doping a side portion of the semiconductor layer 1101 exposed through the fourth recess R4 with impurities. In addition, a silicide layer may be formed by performing a silicide process for ohmic contact with the bit line 120a.

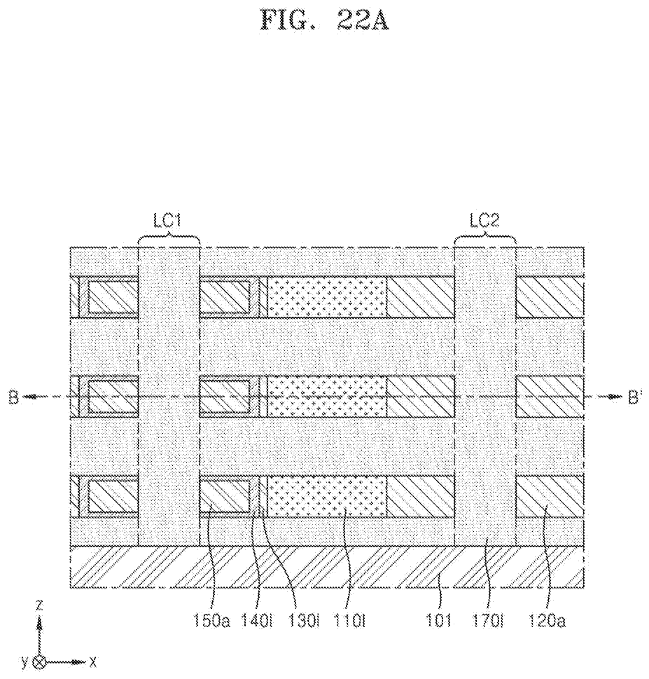

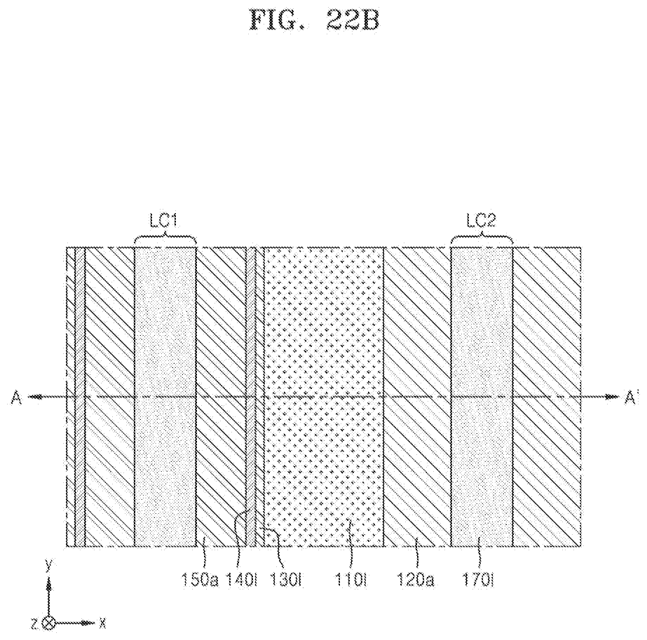

Referring to FIGS. 22A and 22B, the bit line 120a is formed on the semiconductor layer 1101 and the first insulating layer 1701 exposed through the second line cut LC2 and the fourth recess R4. More specifically, first, bit line material layers filling the second line cut LC2 and the fourth recess R4 is formed. Then, the bit line 120a is formed by re-etching the second line cut LC2 and separating the bit line material layers from each other in the vertical direction (z direction). As shown in FIG. 22A, the bit lines 120a may be spaced apart from each other in the vertical direction (z direction). Also, as shown in FIG. 22B, the bit line 120a may have a straight band shape extending in the second horizontal direction (y direction). After the bit line 120a is formed, the second line cut LC2 may be filled with the first insulating layer 1701.

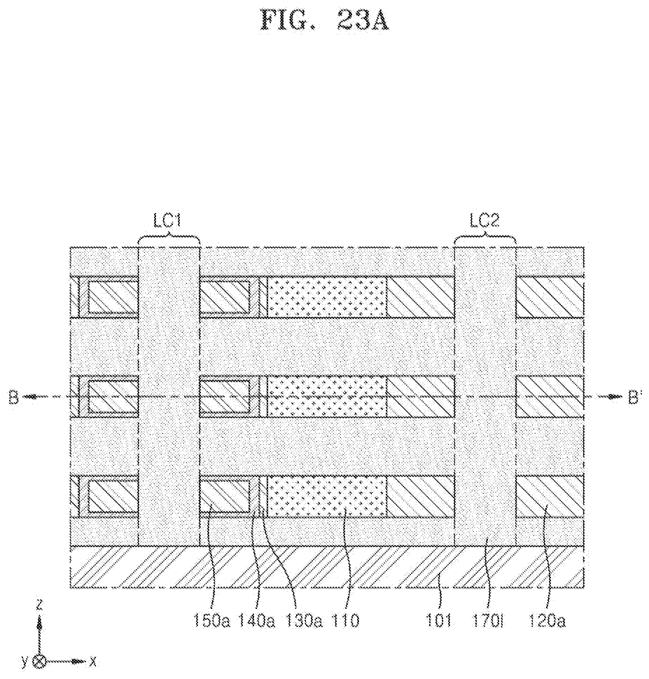

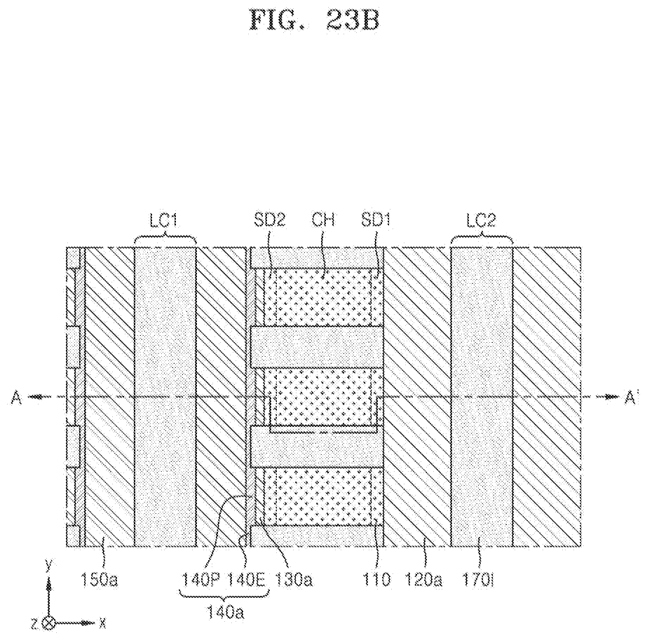

Referring to FIGS. 23A and 23B, trenches spaced apart from each other in the second horizontal direction (y direction) and penetrating the stacked structure are formed. The trench may extend in the vertical direction (z direction), and may expose the upper surface of the substrate 101 through an inner bottom surface thereof. Through the formation of the trench, the semiconductor layer 1101 and the first electrode material layer 1301 are separated from each other in the second horizontal direction (y direction), so that the semiconductor pattern 110 and the first electrode 130a may be formed. The semiconductor pattern 110 may have a rectangular pillar shape extending in the first horizontal direction (x direction). The first electrode 130a may also have a rectangular pillar shape, and accordingly, each of a vertical cross-section and a horizontal cross-section thereof may have a rectangular shape.

Through the formation of the trench, the ferroelectric layer 140a may be formed by etching a part of the side surface of the ferroelectric material layer 1401. Accordingly, the ferroelectric layer 140a may include the extension 140E extending in the second horizontal direction (y direction) and the protrusion 140P on the side surface of the semiconductor pattern 110 on the horizontal cross-section. The trench may be filled with the first insulating layer 1701.

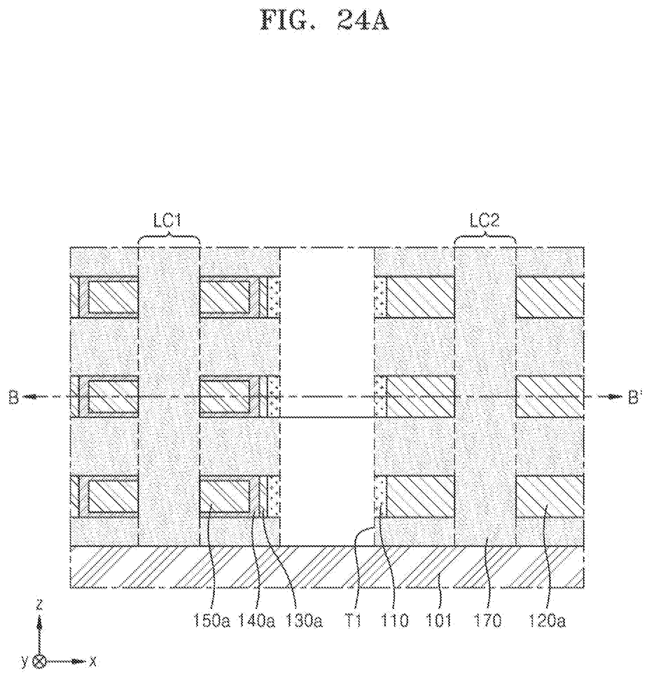

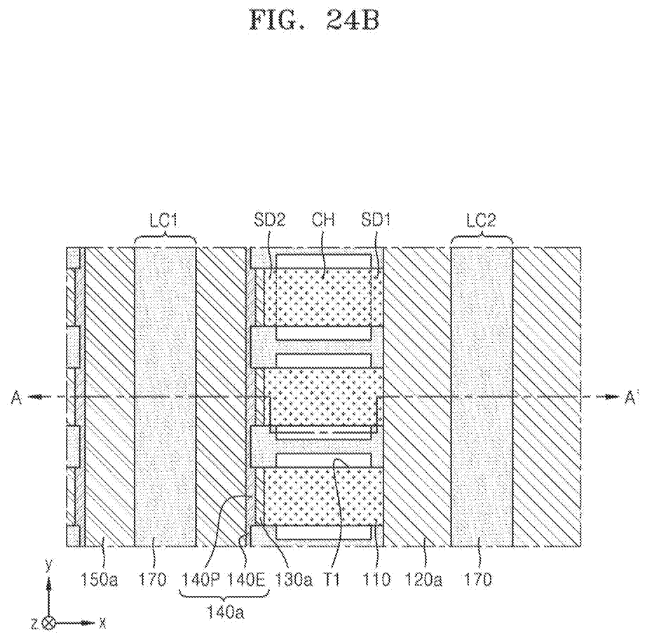

Referring to FIGS. 24A and 24B, the first trench T1 penetrates the stacked structure and is formed between adjacent semiconductor patterns 110 in the second horizontal direction (y direction). The first trench T1 may extend in a vertical direction (z direction) and may expose the upper surface of the substrate 101 on an inner bottom surface thereof. As shown in FIG. 24B, two first trenches T1 may be formed between the adjacent semiconductor patterns 110 in the second horizontal direction (y direction). However, according to an embodiment, one first trench T1 may be formed between the adjacent semiconductor patterns 110 in the second horizontal direction (y direction). The interlayer insulating layer 170 may be formed through the formation of the first trench T1. After the first trench T1 is formed, the word line 160 may be formed by filling the first trench T1 with the gate dielectric layer 162 and a conductive layer.

While aspects of embodiments have been particularly shown and described, it will be understood that various changes in form and details may be made therein without departing from the spirit and scope of the following claims.

1. A three-dimensional (3D) ferroelectric random access memory (FeRAM) comprising:
a substrate;
semiconductor patterns stacked in a vertical direction on the substrate in a multilayer structure with insulating layers therebetween, and spaced apart from each other in a first horizontal direction;
bit lines on first side surfaces of the semiconductor patterns in a second horizontal direction, wherein the second horizontal direction is perpendicular to the first horizontal direction, and the bit lines extend in the first horizontal direction and are spaced apart from each other in the vertical direction;
first electrodes on second side surfaces of the semiconductor patterns in the second horizontal direction, wherein the first electrodes are spaced apart from each other in both the vertical direction and the first horizontal direction;
a ferroelectric layer on the first electrodes in the second horizontal direction, wherein the ferroelectric layer extends in the first horizontal direction;
second electrodes on the ferroelectric layer in the second horizontal direction, wherein the second electrodes extend in the first horizontal direction and are spaced apart from each other in the vertical direction; and
word lines between two adjacent semiconductor patterns among the semiconductor patterns in the first horizontal direction, wherein the word lines extend in the vertical direction.

2. The 3D FeRAM of claim 1, wherein each of the first electrodes has a ‘ [symbol] ’ shape on each of a horizontal cross-section perpendicular to the vertical direction and a vertical cross-section perpendicular to the first horizontal direction.

3. The 3D FeRAM of claim 2, wherein the ferroelectric layer extends in the vertical direction and comprises a ‘ [symbol] ’-shaped portion along each of the horizontal cross-section and the vertical cross-section, in correspondence to the ‘ [symbol] ’ shape of each of the first electrodes.

4. The 3D FeRAM of claim 2, wherein each of the second electrodes comprises:
an extension extending in the first horizontal direction on the horizontal cross-section; and
a protrusion protruding in the second horizontal direction from the extension in correspondence the ‘ [symbol] ’ shape of the ferroelectric layer on the horizontal cross-section and has a rectangular shape filling a ‘ [symbol] ’-shaped inside of the ferroelectric layer on the vertical cross-section.

5. The 3D FeRAM of claim 2, wherein each of the bit lines has a concave-convex shape on a first side surface which extends in the second horizontal direction to contact each of the semiconductor patterns on the horizontal cross-section and a straight line shape which extends in the first horizontal direction on a second side surface opposite to the first side surface.

6. The 3D FeRAM of claim 1, wherein each of the first electrodes has a rectangular shape on both a horizontal cross-section perpendicular to the vertical direction and a vertical cross-section perpendicular to the first horizontal direction.

7. The 3D FeRAM of claim 6, wherein the ferroelectric layer comprises a plurality of ferroelectric layers which are spaced apart from each other in the vertical direction, and
wherein each of the plurality of ferroelectric layers comprises:
an extension extending in the first horizontal direction; and
a protrusion protruding in the second horizontal direction from the extension and contacting each of the first electrodes, wherein the protrusion has a ‘ [symbol] ’ shape.

8. The 3D FeRAM of claim 7, wherein each of the second electrodes has a straight band shape extending in the first horizontal direction on the horizontal cross-section and a rectangular shape extending into a ‘ [symbol] ’-shape of each of the plurality of ferroelectric layers.

9. The 3D FeRAM of claim 1, wherein one or two of the word lines are between two of the semiconductor patterns.

10. The 3D FeRAM of claim 1, wherein the ferroelectric layer comprises a Hf-based oxide film and at least one dopant of Zr, Si, Al, Y, Gd, La, Sc, and Sr.

11. The 3D FeRAM of claim 1, wherein the ferroelectric layer has a multilayer structure comprising at least two different material films.

12. The 3D FeRAM of claim 1, wherein each of the semiconductor patterns comprises at least one of a Si-based semiconductor material, a two-dimensional (2D) semiconductor material, and an oxide semiconductor material.

13. A three-dimensional (3D) ferroelectric random access memory (FeRAM) comprising:
a substrate;
semiconductor patterns stacked in a vertical direction on the substrate in a multilayer structure with insulating layers therebetween, and spaced apart from each other in a first horizontal direction;
bit lines on first side surfaces of the semiconductor patterns in a second horizontal direction, wherein the second horizontal direction is perpendicular to the first horizontal direction, and the bit lines extend in the first horizontal direction and are spaced apart from each other in the vertical direction;
first electrodes on second side surfaces of the semiconductor patterns in the second horizontal direction, wherein the first electrodes are spaced apart from each other in both the vertical direction and the first horizontal direction, and each of the first electrodes has a [symbol] shape on each of a horizontal cross-section perpendicular to the vertical direction and a vertical cross-section perpendicular to the first horizontal direction;
a ferroelectric layer on the first electrodes in the second horizontal direction, wherein the ferroelectric layer extends in the first horizontal direction, and comprises a ‘ [symbol] ’-shaped portion along each of the horizontal cross-section and the vertical cross-section, in correspondence to the ‘ [symbol] ’ shape of each of the first electrodes;
second electrodes on the ferroelectric layer in the second horizontal direction, wherein the second electrodes extend in the first horizontal direction and are spaced apart from each other in the vertical direction, and each of the second electrodes has a rectangular shape filling a ‘ [symbol] ’-shaped inside of the ferroelectric layer on the vertical cross-section; and
word lines between two adjacent semiconductor patterns among the semiconductor patterns in the first horizontal direction, wherein the word lines extend in the vertical direction.

14. The 3D FeRAM of claim 13, wherein each of the second electrodes comprises:
an extension extending in the first horizontal direction on the horizontal cross-section; and
a protrusion protruding in the second horizontal direction from the extension in correspondence to the ‘ [symbol] ’ shape of the ferroelectric layer on the horizontal cross-section.

15. The 3D FeRAM of claim 13, wherein each of the bit lines has a concave-convex shape on a first side surface which extends in the second horizontal direction to contact each of the semiconductor patterns on the horizontal cross-section and a straight line shape which extends in the first horizontal direction on a second side surface opposite to the first side surface.

16. A three-dimensional (3D) ferroelectric random access memory (FeRAM) comprising:
a substrate;
semiconductor patterns stacked in a vertical direction on the substrate in a multilayer structure with insulating layers therebetween, and spaced apart from each other in a first horizontal direction;
bit lines on first side surface of the semiconductor patterns in a second horizontal direction, wherein the second horizontal direction is perpendicular to the first horizontal direction, and the bit lines extend in the first horizontal direction and are spaced apart from each other in the vertical direction;
first electrodes on second side surfaces of the semiconductor patterns in the second horizontal direction, wherein the first electrodes are spaced apart from each other in both the vertical direction and the first horizontal direction, wherein each of a horizontal cross-section perpendicular to the vertical direction and a vertical cross-section perpendicular to the first horizontal direction has a rectangular shape;
ferroelectric layers on the first electrodes in the second horizontal direction, wherein the ferroelectric layers in the first horizontal direction, are spaced apart from each other in the vertical direction, and have a ‘ [symbol] ’ shape on the vertical cross-section;
second electrodes on the ferroelectric layers in the second horizontal direction, wherein the second electrodes extend in the first horizontal direction, are spaced apart from each other in the vertical direction, and each has a rectangular shape filling a ‘ [symbol] ’-shaped inside of each of the ferroelectric layers on the vertical cross-section; and
word lines between two adjacent semiconductor patterns among the semiconductor patterns in the first horizontal direction, wherein the word lines extend in the vertical direction.

17. The 3D FeRAM of claim 16, wherein each of the ferroelectric layers comprises:
an extension extending in the first horizontal direction; and
a protrusion protruding in the second horizontal direction from the extension and contacting each of the first electrodes, and
wherein the extension and the protrusion form a ‘T’ shape in correspondence to one of the semiconductor patterns.

18. The 3D FeRAM of claim 16, wherein each of the second electrodes has a straight band shape extending in the first horizontal direction on the horizontal cross-section.

19. The 3D FeRAM of claim 16, wherein each of the bit lines has a straight band shape extending in the first horizontal direction.

20-26. (canceled)
